(19) United States
(12) Patent Application Publication
(10) Pub. No.: US 2020/0026080 A1
(43) Pub. Date: Jan. 23, 2020

(54) WAVELENGTH COMBINER PHOTONIC INTEGRATED CIRCUIT WITH EDGE COUPLING OF LASERS

(71) Applicant: North Inc., Kitchener (CA)

(72) Inventors: Jörg Pierer, Alpnach (CH); Rony Jose James, Alpnach (CH); Stefan Mohrdiek, Affoltern am Albis (CH); Douglas R. Dykaar, Waterloo (CA)

(21) Appl. No.: 16/203,278

(22) Filed: Nov. 28, 2018

Related U.S. Application Data
(60) Provisional application No. 62/591,550, filed on Nov. 28, 2017.
(60) Provisional application No. 62/597,294, filed on Dec. 11, 2017.
(60) Provisional application No. 62/608,749, filed on Dec. 21, 2017.
(60) Provisional application No. 62/609,870, filed on Dec. 22, 2017.
(60) Provisional application No. 62/620,600, filed on Jan. 23, 2018.
(60) Provisional application No. 62/760,835, filed on Nov. 13, 2018.

(51) Int. Cl. G02B 27/01; H01S 5/40; H01S 5/022; G02B 26/10; G02B 26/08

(52) U.S. Cl. CPC G02B 27/0172; H01S 5/4093; H01S 5/4012; H01S 5/02292; G02B 2027/0178; H01S 5/02236; G02B 26/10; G02B 26/0816; H01S 5/02288

(57) ABSTRACT

Systems, devices, and methods of manufacturing optical engines and laser projectors that are well-suited for use in wearable heads-up displays (WHUDs) are described. Generally, the optical engines of the present disclosure integrate a plurality of laser diodes (e.g., 3 laser diodes, 4 laser diodes) within a single, hermetically or partially hermetically sealed, encapsulated package. Photonic integrated circuits may be used to wavelength multiplex beams of light emitted by the plurality of laser diodes into a coaxially superimposed aggregate beam. Such optical engines may have various advantages over existing designs including, for example, smaller volumes, better manufacturability, faster modulation speed, etc. WHUDs that employ such optical engines and laser projectors are also described.

### BACKGROUND

### Technical Field

The present disclosure is generally directed to systems, devices, and methods relating to optical engines, for example, optical engines for laser projectors used in wearable heads-up displays or other applications.

### Description of the Related Art

A projector is an optical device that projects or shines a pattern of light onto another object (e.g., onto a surface of another object, such as onto a projection screen) in order to display an image or video on that other object. A projector necessarily includes a light source, and a laser projector is a projector for which the light source comprises at least one laser. The at least one laser is temporally modulated to provide a pattern of laser light and usually at least one controllable mirror is used to spatially distribute the modulated pattern of laser light over a two-dimensional area of another object. The spatial distribution of the modulated pattern of laser light produces an image at or on the other object. In conventional scanning laser projectors, at least one controllable mirror may be used to control the spatial distribution, and may include: a single digital micromirror (e.g., a microelectromechanical system (“MEMS”) based digital micromirror) that is controllably rotatable or deformable in two dimensions, or two digital micromirrors that are each controllably rotatable or deformable about a respective dimension, or a digital light processing (“DLP”) chip comprising an array of digital micromirrors.

In a conventional laser projector comprising an RGB (red/green/blue) laser module with a red laser diode, a green laser diode, and a blue laser diode, each respective laser diode may have a corresponding respective focusing lens. Each of the laser diodes of a laser module are typically housed in a separate package (e.g., a TO-38 package or “can”). The relative positions of the laser diodes, the focusing lenses, and the at least one controllable mirror are all tuned and aligned so that each laser beam impinges on the at least one controllable mirror with substantially the same spot size and with substantially the same rate of convergence (so that all laser beams will continue to have substantially the same spot size as they propagate away from the laser projector towards, e.g., a projection screen). In a conventional laser projector, it is usually possible to come up with such a configuration for all these elements because the overall form factor of the device is not a primary design consideration. However, in applications for which the form factor of the laser projector is an important design element, it can be very challenging to find a configuration for the laser diodes, the focusing lenses, and the at least one controllable mirror that sufficiently aligns the laser beams (at least in terms of spot size, spot position, and rate of convergence) while satisfying the form factor constraints.

A head-mounted display is an electronic device that is worn on a user's head and, when so worn, secures at least one electronic display within a viewable field of at least one of the user's eyes, regardless of the position or orientation of the user's head. A wearable heads-up display is a head-mounted display that enables the user to see displayed content but also does not prevent the user from being able to see their external environment. The “display” component of a wearable heads-up display is either transparent or at a periphery of the user's field of view so that it does not completely block the user from being able to see their external environment. A “combiner” component of a wearable heads-up display is the physical structure where display light and environmental light merge as one within the user's field of view. The combiner of a wearable heads-up display is typically transparent to environmental light but includes some optical routing mechanism to direct display light into the user's field of view.

Examples of wearable heads-up displays include: the Google Glass®, the Optinvent Ora®, the Epson Moverio®, and the Sony Glasstron®, just to name a few.

The optical performance of a wearable heads-up display is an important factor in its design. When it comes to face-worn devices, users also care a lot about aesthetics and comfort. This is clearly highlighted by the immensity of the eyeglass (including sunglass) frame industry. Independent of their performance limitations, many of the aforementioned examples of wearable heads-up displays have struggled to find traction in consumer markets because, at least in part, they lack fashion appeal or comfort. Most wearable heads-up displays presented to date employ relatively large components and, as a result, are considerably bulkier, less comfortable and less stylish than conventional eyeglass frames.

### Direct Laser Writing

Femtosecond laser micro-machining is a direct-laser-write and rapid prototyping technique that provides great potential for optical device fabrication. Strong focusing of femtosecond laser light into transparent glass can induce positive refractive index modifications up to 0.01 refractive index units (RIU) within the material and without surface damage. Since then, ultrafast (femto/pico-second) lasers have been shown to enable flexible 3D structuring of various glasses, and has led to the demonstration of many types of optical devices (waveguides, couplers, Bragg gratings, waveplates, etc.) that serve as building blocks for 3D optical circuits.

Direct-laser-writing uses ultrashort laser pulses to confine strong nonlinear optical interactions that may induce, for example, positive or negative refractive index changes in bulk transparent materials for creating optical waveguides (WGs). The mechanisms by which direct-laser-write modifications occur include, but are not limited to, multiphoton ionization, avalanche ionization, electron-atom collisions, plasma interactions, thermal effects (e.g. diffusion, heat accumulation), energy dissipation, and material cooling leading to inhomogeneous solidification. For direct-laser-writing waveguides, waveguide performance can be tuned and optimized by, but not limited to, the writing laser's properties (pulse duration, pulse temporal shape, bandwidth and shape, pulse repetition rate, wavelength, polarization, and beam spatial shape) and the focusing conditions (lens numerical aperture, air/liquid immersion, translation direction and speeds).

### BRIEF SUMMARY

An optical engine may be summarized as including a base substrate; a plurality of laser diodes, each of the plurality of laser diodes bonded directly or indirectly to the base substrate; at least one laser diode driver circuit operatively coupled to the plurality of laser diodes to selectively drive current to the plurality of laser diodes; a cap including at least one wall and at least one optical window that, together with the base substrate, define an interior volume sized and dimensioned to receive at least the plurality of laser diodes, the cap being bonded to the base substrate to provide a hermetic or partially hermetic seal between the interior volume of the cap and a volume exterior to the cap, and the optical window positioned and oriented to allow beams of light emitted from the plurality of laser diodes to exit the interior volume; a photonic integrated circuit bonded to the base substrate proximate the optical window of the cap, the photonic integrated circuit including at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge; and a plurality of coupling lenses bonded to the base substrate between the optical window of the cap and the input optical edge of the photonic integrated circuit, each of the plurality of coupling lenses positioned and oriented to couple respective ones of the beams of light emitted from the plurality of laser diodes to the at least one input optical edge of the photonic integrated circuit.

The optical engine may further include a collimation lens positioned and oriented to receive and collimate the aggregate beam of light from the output optical edge of the photonic integrated circuit. The collimation lens may include an achromatic lens. The collimation lens may include an apochromatic lens.

The optical engine may further include at least one diffractive optical element positioned and oriented to receive the aggregate beam of light, in operation, the at least one diffractive optical element provides wavelength dependent focus correction for the aggregate beam of light. The cap may include a rectangular shaped sidewall, and the optical window may delimit a portion of the sidewall.

The optical engine may further include a plurality of chip submounts bonded to the base substrate, wherein each of the laser diodes are bonded to a corresponding one of the plurality of chip submounts. The plurality of laser diodes may include a red laser diode to provide a red laser light, a green laser diode to provide a green laser light, a blue laser diode to provide a blue laser light, and an infrared laser diode to provide infrared laser light. The base substrate may be formed from at least one of low temperature co-fired ceramic (LTCC), aluminum nitride (AlN), alumina, or Kovar®. The at least one laser diode driver circuit may be bonded to a first surface of the base substrate, and the plurality of laser diodes and the cap may be bonded to a second surface of the base substrate, the second surface of the base substrate opposite the first surface of the base substrate. The at least one laser diode driver circuit, the plurality of laser diodes, and the cap may be bonded to a first surface of the base substrate. Each of the laser diodes may include one of an edge emitter laser or a vertical-cavity surface-emitting laser (VCSEL).

The photonic integrated circuit may include a plurality of waveguides, each waveguide of the plurality of waveguides to receive laser light from a respective laser diode of the plurality of laser diodes. Each waveguide of the plurality of waveguides may be optimized to receive and output laser light having a wavelength corresponding to the wavelength of laser light received from the respective laser diode. The plurality of waveguides may include a waveguide combiner. The waveguide combiner may include at least one of: a directional coupler, Y-branch, whispering gallery mode, or multi-mode interface coupler. Each waveguide of the plurality of waveguides may include an input facet to receive laser light from a respective laser diode of the plurality of laser diodes and an output facet to output the received laser light, a spacing between the output facets of each waveguide being smaller than a spacing between the input facets of each waveguide.

A wearable heads-up display (WHUD) may be summarized as including a support structure that in use is worn on the head of a user; a laser projector carried by the support structure, the laser projector including optical engine, including a base substrate; a plurality of laser diodes, each of the plurality of laser diodes bonded directly or indirectly to the base substrate; at least one laser diode driver circuit operatively coupled to the plurality of laser diodes to selectively drive current to the plurality of laser diodes; a cap including at least one wall and at least one optical window that, together with the base substrate, define an interior volume sized and dimensioned to receive at least the plurality of laser diodes, the cap being bonded to the base substrate to provide a hermetic or partially hermetic seal between the interior volume of the cap and a volume exterior to the cap, and the optical window positioned and oriented to allow beams of light emitted from the plurality of laser diodes to exit the interior volume; a photonic integrated circuit bonded to the base substrate proximate the optical window of the cap, the photonic integrated circuit including at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge; and a plurality of coupling lenses bonded to the base substrate between the optical window of the cap and the input optical edge of the photonic integrated circuit, each of the plurality of coupling lenses positioned and oriented to couple respective ones of the beams of light emitted from the plurality of laser diodes to the at least one input optical edge of the photonic integrated circuit; and at least one scan mirror positioned to receive the aggregate beam of light output at the output optical edge of the photonic integrated circuit, the at least one scan mirror controllably orientable to redirect the aggregate beam of light over a range of angles.

The WHUD may further include a processor communicatively coupled to the laser projector to modulate the generation of light signals.

The WHUD may further include a transparent combiner carried by the support structure and positioned within a field of view of the user, in operation the transparent combiner directs laser light from an output of the laser projector into the field of view of the user.

The optical engine of the WHUD may further include a collimation lens positioned and oriented to receive and collimate the aggregate beam of light from the output optical edge of the photonic integrated circuit. The collimation lens may include an achromatic lens or an apochromatic lens.

The optical engine of the WHUD may further include at least one diffractive optical element positioned and oriented to receive the aggregate beam of light, in operation, the at least one diffractive optical element provides wavelength dependent focus correction for the aggregate beam of light.

The photonic integrated circuit of the WHUD may include a plurality of waveguides, each waveguide of the plurality of waveguides to receive laser light from a respective laser diode of the plurality of laser diodes. Each waveguide of the plurality of waveguides may be optimized to receive and output laser light having a wavelength corresponding to the wavelength of laser light received from the respective laser diode. The plurality of waveguides may include a waveguide combiner. The waveguide combiner may include at least one of: a directional coupler, Y-branch, whispering gallery mode, or multi-mode interface coupler. Each waveguide of the plurality of waveguides may include an input facet to receive laser light from a respective laser diode of the plurality of laser diodes and an output facet to output the received laser light, a spacing between the output facets of each waveguide being smaller than a spacing between the input facets of each waveguide.

The optical engine of the WHUD may further include a plurality of chip submounts bonded to the base substrate, wherein each of the laser diodes are bonded to a corresponding one of the plurality of chip submounts. The plurality of laser diodes may include a red laser diode to provide a red laser light, a green laser diode to provide a green laser light, a blue laser diode to provide a blue laser light, and an infrared laser diode to provide infrared laser light.

The at least one laser diode driver circuit may be bonded to a first surface of the base substrate, and the plurality of laser diodes and the cap may be bonded to a second surface of the base substrate, the second surface of the base substrate opposite the first surface of the base substrate. The at least one laser diode driver circuit, the plurality of laser diodes, and the cap may be bonded to a first surface of the base substrate.

Each of the laser diodes comprises one of an edge emitter laser or a vertical-cavity surface-emitting laser (VCSEL).

A laser projector may be summarized as including an optical engine, including a base substrate; a plurality of laser diodes, each of the plurality of laser diodes bonded directly or indirectly to the base substrate; at least one laser diode driver circuit operatively coupled to the plurality of laser diodes to selectively drive current to the plurality of laser diodes; a cap comprising at least one wall and at least one optical window that, together with the base substrate, define an interior volume sized and dimensioned to receive at least the plurality of laser diodes, the cap being bonded to the base substrate to provide a hermetic or partially hermetic seal between the interior volume of the cap and a volume exterior to the cap, and the optical window positioned and oriented to allow beams of light emitted from the plurality of laser diodes to exit the interior volume; a photonic integrated circuit bonded to the base substrate proximate the optical window of the cap, the photonic integrated circuit comprising at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge; and a plurality of coupling lenses bonded to the base substrate between the optical window of the cap and the input optical edge of the photonic integrated circuit, each of the plurality of coupling lenses positioned and oriented to couple respective ones of the beams of light emitted from the plurality of laser diodes to the at least one input optical edge of the photonic integrated circuit; and at least one scan mirror positioned to receive the aggregate beam of light output at the output optical edge of the photonic integrated circuit, the at least one scan mirror controllably orientable to redirect the aggregate beam of light over a range of angles.

The laser projector may further include a processor communicatively coupled to optical engine to modulate the generation of light signals.

The optical engine of the laser projector may further include a collimation lens positioned and oriented to receive and collimate the aggregate beam of light from the output optical edge of the photonic integrated circuit. The collimation lens may include an achromatic lens or an apochromatic lens.

The optical engine of the laser projector may further include at least one diffractive optical element positioned and oriented to receive the aggregate beam of light, in operation, the at least one diffractive optical element provides wavelength dependent focus correction for the aggregate beam of light.

The photonic integrated circuit may include a plurality of waveguides, each waveguide of the plurality of waveguides to receive laser light from a respective laser diode of the plurality of laser diodes. Each waveguide of the plurality of waveguides may be optimized to receive and output laser light having a wavelength corresponding to the wavelength of laser light received from the respective laser diode. The plurality of waveguides may include a waveguide combiner. The waveguide combiner may include at least one of: a directional coupler, Y-branch, whispering gallery mode, or multi-mode interface coupler. Each waveguide of the plurality of waveguides may include an input facet to receive laser light from a respective laser diode of the plurality of laser diodes and an output facet to output the received laser light, a spacing between the output facets of each waveguide being smaller than a spacing between the input facets of each waveguide.

The optical engine of the laser projector may further include a plurality of chip submounts bonded to the base substrate, wherein each of the laser diodes are bonded to a corresponding one of the plurality of chip submounts. The plurality of laser diodes may include a red laser diode to provide a red laser light, a green laser diode to provide a green laser light, a blue laser diode to provide a blue laser light, and an infrared laser diode to provide infrared laser light.

The at least one laser diode driver circuit may be bonded to a first surface of the base substrate, and the plurality of laser diodes and the cap may be bonded to a second surface of the base substrate, the second surface of the base substrate opposite the first surface of the base substrate. The at least one laser diode driver circuit, the plurality of laser diodes, and the cap may be bonded to a first surface of the base substrate. Each of the laser diodes may include one of an edge emitter laser or a vertical-cavity surface-emitting laser (VCSEL).

A method of operating an optical engine, the optical engine including a plurality of laser diodes hermetically or partially hermetically sealed in an encapsulated package, may be summarized as including causing the plurality of laser diodes to generate beams of laser light through an optical window in the encapsulated package; coupling the beams of laser light into an input optical edge of a photonic integrated circuit; and wavelength multiplexing, by the photonic integrated circuit, the beams of laser light to generate an aggregate beam of light at an output optical edge of the photonic integrated circuit.

The method may further include collimating, by a collimation lens, the aggregate beam of light that exits from the output optical edge of the photonic integrated circuit. Collimating the aggregate beam of light may include collimating the aggregate beam of light using an achromatic lens or an apochromatic lens.

The method may further include correcting, by at least one diffractive element, wavelength dependent focus for the aggregate beam of light. Causing the plurality of laser diodes to generate laser light may include causing a red laser diode to generate red laser light, causing a green laser diode to generate green laser light, causing a blue laser diode to generate blue laser light, and causing an infrared laser diode to generate infrared laser light. Coupling the beams of laser light into an input optical edge of a photonic integrated circuit may include coupling the beams of laser light into an input optical edge of a photonic integrated circuit via a plurality of coupling lenses.

Wavelength multiplexing, by the photonic integrated circuit, the beams of laser light may include receiving, by each waveguide of a plurality of waveguides, laser light from a respective laser diode of the plurality of laser diodes, and outputting, by the plurality of waveguides, an aggregate beam of light. Wavelength multiplexing, by the photonic integrated circuit, the beams of laser light may include receiving, by each input facet of a plurality of input facets of a waveguide combiner, laser light from a respective laser diode of the plurality of laser diodes, and outputting, by the plurality of waveguides, a coaxially superimposed aggregate beam of light. Wavelength multiplexing, by the photonic integrated circuit, the beams of laser light may include receiving, by an input facet of each waveguide of a plurality of waveguides, laser light from a respective laser diode of the plurality of laser diodes, and outputting, by an output facet of each waveguide of the plurality of waveguides, a beam of light, a spacing between the output facets of each waveguide being smaller than a spacing between the input facets of each waveguide to produce an aggregate beam of light.

An optical engine may be summarized as including a base substrate; a plurality of laser diodes, each of the plurality of laser diodes bonded directly or indirectly to the base substrate; a cap comprising at least one wall that, with the base substrate, defines an interior volume sized and dimensioned to receive at least the plurality of laser diodes, the cap being bonded to the base substrate to provide a hermetic or partially hermetic seal between the interior volume of the cap and a volume exterior to the cap; and a photonic integrated circuit comprising at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge.

The optical engine may further include a plurality of coupling lenses positioned between the plurality of laser diodes and the input optical edge of the photonic integrated circuit, each of the plurality of coupling lenses positioned and oriented to couple respective ones of the beams of light emitted from the plurality of laser diodes to the at least one input optical edge of the photonic integrated circuit. Each of the plurality of laser diodes may be positioned immediately adjacent the at least one optical input edge of the photonic integrated circuit. The at least one optical input edge of the photonic integrated circuit may be positioned inside the interior volume and the at least one optical output edge of the photonic integrated circuit may be positioned outside of the interior volume. The cap may include at least one optical window positioned and oriented to allow beams of light emitted from the plurality of laser diodes to exit the interior volume.

The optical engine may further include a collimation lens positioned and oriented to receive and collimate the aggregate beam of light from the output optical edge of the photonic integrated circuit. The collimation lens may include an achromatic lens or an apochromatic lens.

The optical engine may further include at least one diffractive optical element positioned and oriented to receive the aggregate beam of light, in operation, the at least one diffractive optical element providing wavelength dependent focus correction for the aggregate beam of light. The cap may include a rectangular shaped sidewall, and the optical window may delimit a portion of the sidewall.

The optical engine may further include a plurality of chip submounts bonded to the base substrate, wherein each of the laser diodes are bonded to a corresponding one of the plurality of chip submounts. The plurality of laser diodes may include a red laser diode to provide a red laser light, a green laser diode to provide a green laser light, a blue laser diode to provide a blue laser light, and an infrared laser diode to provide infrared laser light. The base substrate is formed from at least one of low temperature co-fired ceramic (LTCC), aluminum nitride (AlN), alumina, or Kovar®.

The optical engine may further include at least one laser diode driver circuit operatively coupled to the plurality of laser diodes to selectively drive current to the plurality of laser diodes. The at least one laser diode driver circuit may be bonded to a first surface of the base substrate, and the plurality of laser diodes and the cap may be bonded to a second surface of the base substrate, the second surface of the base substrate opposite the first surface of the base substrate. The at least one laser diode driver circuit, the plurality of laser diodes, and the cap may be bonded to a first surface of the base substrate.

Each of the laser diodes may include one of an edge emitter laser or a vertical-cavity surface-emitting laser (VCSEL).

The photonic integrated circuit may include a plurality of waveguides, each waveguide of the plurality of waveguides to receive laser light from a respective laser diode of the plurality of laser diodes. Each waveguide of the plurality of waveguides may be optimized to receive and output laser light having a wavelength corresponding to the wavelength of laser light received from the respective laser diode. The plurality of waveguides may include a waveguide combiner. The waveguide combiner may include at least one of: a directional coupler, Y-branch, whispering gallery mode, or multi-mode interface coupler. Each waveguide of the plurality of waveguides may include an input facet to receive laser light from a respective laser diode of the plurality of laser diodes and an output facet to output the received laser light, a spacing between the output facets of each waveguide being smaller than a spacing between the input facets of each waveguide.

A method of manufacturing an optical engine may be summarized as including: bonding a plurality of laser diodes directly or indirectly to a base substrate; bonding a cap to the base substrate, the cap comprising at least one wall that, with the base substrate, defines an interior volume sized and dimensioned to receive at least the plurality of laser diodes, the cap being bonded to the base substrate to provide a hermetic or partially hermetic seal between the interior volume of the cap and a volume exterior to the cap; and bonding a photonic integrated circuit comprising at least one optical input edge and at least one optical output edge to the base substrate, in operation, the photonic integrated circuit receives a plurality of beams of light at the at least one optical input edge and wavelength multiplexes the plurality of beams of light to provide an aggregated beam of light at the output optical edge.

The method of manufacturing an optical engine may further include: bonding at least one of the laser diodes indirectly to the base substrate by bonding the at least one laser diode to a respective chip submount; and bonding the chip submount to the base substrate.

The method of manufacturing an optical engine may further include: bonding each of the laser diodes indirectly to the base substrate by bonding each laser diode to a respective chip submount; and bonding each chip submount to the base substrate. Bonding each laser diode to a respective chip submount may include bonding each laser diode to a respective chip submount using a eutectic gold tin (AuSn) solder process. Bonding each chip submount to the base substrate may include step-soldering each chip submount to the first base substrate. Bonding each chip submount to the base substrate may include bonding each chip submount to the base substrate using at least one of a reflow oven process, thermosonic bonding, thermocompression bonding, transient liquid phase (TLP) bonding, or laser soldering. Bonding each chip submount to the base substrate may include bonding a chip submount that has a red laser diode bonded thereto, bonding a chip submount that has a green laser diode bonded thereto, bonding a chip submount that has a blue laser diode bonded thereto, and bonding a chip submount that has an infrared laser diode bonded thereto. Bonding each chip submount to the base substrate may include soldering each chip submount to the base substrate using a reactive multi-layer foil material preform.

The method of manufacturing an optical engine may further include: bonding a plurality of coupling lenses positioned between the plurality of laser diodes and the input optical edge of the photonic integrated circuit, each of the plurality of coupling lenses positioned and oriented to couple respective ones of the beams of light emitted from the plurality of laser diodes to the at least one input optical edge of the photonic integrated circuit.

Bonding the photonic integrated circuit to the base substrate may include bonding the input edge of the photonic integrated circuit immediately adjacent the plurality of laser diodes. The method of manufacturing an optical engine may further include positioning the at least one optical input edge of the photonic integrated circuit inside the interior volume and the at least one optical output edge of the photonic integrated circuit outside of the interior volume. Bonding the photonic integrated circuit to the base substrate may include bonding the input edge of the photonic integrated circuit against at least one optical window in the cap positioned and oriented to allow beams of light emitted from the plurality of laser diodes to exit the interior volume.

The method of manufacturing an optical engine may further include providing a coupling between at least one laser diode driver circuit and the plurality of laser diodes, in operation the at least one laser diode driver circuit selectively drives current to the laser diodes. Bonding the plurality of laser diodes directly or indirectly to a base substrate may include bonding the laser diodes directly or indirectly to a first surface of the base substrate, and bonding a cap to the base substrate may include bonding a cap to the first surface of the base substrate, and the method of manufacturing an optical engine may further include bonding the at least one laser diode driver circuit to a second surface of the base substrate, the second surface of the base substrate opposite the first surface of the base substrate. Bonding the plurality of laser diodes directly or indirectly to a base substrate may include bonding the laser diodes directly or indirectly to a first surface of the base substrate, and bonding a cap to the base substrate may include bonding a cap to the first surface of the base substrate, and T\the method of manufacturing an optical engine may further include bonding the at least one laser diode driver circuit to the first surface of the base substrate.

The method of manufacturing an optical engine may further include providing the base substrate, wherein the base substrate is formed from one of low temperature co-fired ceramic, aluminum nitride (AlN), Kovar®, or alumina. Bonding a cap to the base substrate may include bonding a cap to the base substrate using at least one of a seam welding process, a laser assisted soldering process, or a diffusion bonding process.

The method of manufacturing an optical engine may further include, prior to bonding the cap to the base substrate, flooding the interior volume with an oxygen rich atmosphere. The method of manufacturing an optical engine may further include positioning and orienting a collimation lens to receive and collimate the aggregate beam of light from the output optical edge of the photonic integrated circuit.

The method of manufacturing an optical engine may further include laser writing the photonic integrated circuit into a writeable glass before bonding the photonic integrated circuit to the base substrate. Laser writing the photonic integrated circuit into writeable glass may include laser writing a plurality of waveguides into the writeable glass, each waveguide of the plurality of waveguides being written for a respective one laser diode of the plurality of laser diodes. Laser writing a plurality of waveguides into the writeable glass may include writing a waveguide combiner into the writeable glass. Writing a waveguide combiner into the writeable glass may include writing at least one of: a directional coupler, Y-branch, whispering gallery mode, or multi-mode interface coupler. Laser writing a plurality of waveguides into the writeable glass may include laser writing each waveguide of the plurality of waveguide to have an input facet to receive laser light from a respective laser diode of the plurality of laser diodes and an output facet to output the received laser light, a spacing between the output facets of each waveguide being smaller than a spacing of the input facets of each waveguide.

A method of manufacturing an optical engine may be summarized as including: bonding a plurality of laser diodes directly or indirectly to a base substrate; bonding a cap to the base substrate, the cap comprising at least one wall that, with the base substrate, defines an interior volume sized and dimensioned to receive at least the plurality of laser diodes, the cap being bonded to the base substrate to provide a hermetic or partially hermetic seal between the interior volume of the cap and a volume exterior to the cap; bonding writeable glass to the base substrate; and after bonding the writeable glass to the base substrate, writing a photonic integrated circuit into the writeable glass, the photonic integrated circuit comprising at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge.

The method of manufacturing an optical engine may further include: bonding at least one of the laser diodes indirectly to the base substrate by bonding the at least one laser diode to a respective chip submount; and bonding the chip submount to the base substrate.

The method of manufacturing an optical engine may further include: bonding each of the laser diodes indirectly to the base substrate by bonding each laser diode to a respective chip submount; and bonding each chip submount to the base substrate. Bonding each laser diode to a respective chip submount may include bonding each laser diode to a respective chip submount using a eutectic gold tin (AuSn) solder process. Bonding each chip submount to the base substrate may include step-soldering each chip submount to the first base substrate. Bonding each chip submount to the base substrate may include bonding each chip submount to the base substrate using at least one of a reflow oven process, thermosonic bonding, thermocompression bonding, transient liquid phase (TLP) bonding, or laser soldering. Bonding each chip submount to the base substrate may include bonding a chip submount that has a red laser diode bonded thereto, bonding a chip submount that has a green laser diode bonded thereto, bonding a chip submount that has a blue laser diode bonded thereto, and bonding a chip submount that has an infrared laser diode bonded thereto. Bonding each chip submount to the base substrate may include soldering each chip submount to the base substrate using a reactive multi-layer foil material preform.

Bonding the writeable glass to the base substrate may include bonding the input edge of the photonic integrated circuit immediately adjacent the plurality of laser diodes. The method of manufacturing an optical engine may further include bonding at least one optical window to the cap, the optical window positioned and oriented to allow beams of light emitted from the plurality of laser diodes to exit the interior volume. Bonding the writeable glass to the base substrate may include bonding the writeable glass to the base substrate and the cap to form the optical window from the writeable glass.

The method of manufacturing an optical engine may further include providing a coupling between at least one laser diode driver circuit and the plurality of laser diodes, in operation the at least one laser diode driver circuit selectively drives current to the laser diodes. Bonding the plurality of laser diodes directly or indirectly to a base substrate may include bonding the laser diodes directly or indirectly to a first surface of the base substrate, bonding a cap to the base substrate may include bonding a cap to the first surface of the base substrate, and bonding writeable glass to the base substrate may include bonding the writeable glass to the first surface of the base substrate, and the method of manufacturing an optical engine may further include bonding the at least one laser diode driver circuit to a second surface of the base substrate, the second surface of the base substrate opposite the first surface of the base substrate. Bonding the plurality of laser diodes directly or indirectly to a base substrate may include bonding the laser diodes directly or indirectly to a first surface of the base substrate, bonding a cap to the base substrate may include bonding a cap to the first surface of the base substrate, and bonding writeable glass to the base substrate may include bonding the writeable glass to the first surface of the base substrate, and the method of manufacturing an optical engine may further include bonding the at least one laser diode driver circuit to the first surface of the base substrate.

The method of manufacturing an optical engine may further include: providing the base substrate, wherein the base substrate is formed from one of low temperature co-fired ceramic, aluminum nitride (AlN), Kovar®, or alumina. Bonding a cap to the base substrate may include bonding a cap to the base substrate using at least one of a seam welding process, a laser assisted soldering process, or a diffusion bonding process. The method of manufacturing an optical engine may further include, prior to bonding the cap to the base substrate, flooding the interior volume with an oxygen rich atmosphere. The method of manufacturing an optical engine may further include positioning and orienting a collimation lens to receive and collimate the aggregate beam of light from the output optical edge of the photonic integrated circuit.

Laser writing the photonic integrated circuit into the writeable glass may include laser writing a plurality of waveguides into the writeable glass, each waveguide of the plurality of waveguides being written for a respective one laser diode of the plurality of laser diodes. Laser writing a plurality of waveguides into the writeable glass comprises writing a waveguide combiner into the writeable glass. Writing a waveguide combiner into the writeable glass comprises writing at least one of: a directional coupler, Y-branch, whispering gallery mode, or multi-mode interface coupler. Laser writing a plurality of waveguides into the writeable glass comprises laser writing each waveguide of the plurality of waveguide to have an input facet to receive laser light from a respective laser diode of the plurality of laser diodes and an output facet to output the received laser light, a spacing between the output facets of each waveguide being smaller than a spacing of the input facets of each waveguide.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements, and may have been solely selected for ease of recognition in the drawings.

FIG. 1A is a left side, sectional elevational view of an optical engine, in accordance with the present systems, devices, and methods.

FIG. 1B is a front side, sectional elevational view of the optical engine also shown in FIG. 1A, in accordance with the present systems, devices, and methods.

FIG. 2 is a flow diagram of a method of operating an optical engine, in accordance with the present systems, devices, and methods.

FIG. 3 is a schematic diagram of a wearable heads-up display with a laser projector that includes an optical engine, and a transparent combiner in a field of view of an eye of a user, in accordance with the present systems, devices, and methods.

FIG. 4 is an isometric view of a wearable heads-up display with a laser projector that includes an optical engine, in accordance with the present systems, devices, and methods.

FIG. 5 is a flow diagram of a method of manufacturing an optical engine, in accordance with the present systems, devices, and methods.

FIG. 6 is a top plan view of a photonic integrated circuit for wavelength multiplexing followed by a common collimation lens and an optional diffractive optical element, in accordance with the present systems, devices, and methods.

FIG. 7 is a left side sectional elevational view of an optical engine that includes a plurality of laser diodes inside a hermetically or partially hermetically sealed package coupled to a photonic integrated circuit for wavelength multiplexing, and a common collimation lens and an optional diffractive optical element, in accordance with the present systems, devices, and methods.

FIG. 8 is a schematic diagram of a laser writing system which can be used to write photonic integrated circuits

FIG. 9 is a flow diagram of a method of manufacturing an optical engine including writing a photonic integrated circuit, in accordance with the present systems, devices, and methods.

FIG. 10 is a schematic diagram of a laser writing system which can be used to write photonic integrated circuits in writeable glass already bonded to a substrate.

FIG. 11A is a top side sectional elevational view of an optical engine that includes a plurality of laser diodes which output beams of light to a beam combiner which produces an aggregate beam.

FIG. 11B is an isometric view of an optical engine including an insulating cover which prevents undesired electrical signal transmission from electrical connections.

FIG. 11C is a top side sectional elevational view of an optical engine having components which are not bonded to a single base substrate.

FIG. 11D is a top side sectional elevational view of an optical engine having collimation lenses which redirect beams to a beam combiner which does not directly line up with outputs of laser diodes of the optical engine.

FIG. 11E is a top side sectional elevational view of an optical engine having a collimation lens which collimates an aggregate beam output from a beam combiner.

FIG. 12 is an isometric view of a laser diode, showing a fast axis and a slow axis of a light beam generated by the laser diode, in accordance with the present systems, devices, and methods.

FIG. 13A is a left side sectional view of a set of collimation lenses for collimating a beam of light separately along different axes.

FIG. 13B is a top side sectional elevational view of the set of collimation lenses of FIG. 13A.

FIGS. 13C and 13D are isometric views of exemplary lens shapes which could be used as lenses in the implementation of FIGS. 13A and 13B.

FIG. 14A is a left side sectional view of a set of collimation lenses for circularizing and collimating a beam of light.

FIG. 14B is a top side sectional elevational view of the set of collimation lenses of FIG. 14A.

FIGS. 14C and 14D are isometric views of exemplary lens shapes which could be used as a collimation lens in the implementation of FIGS. 14A and 14B.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

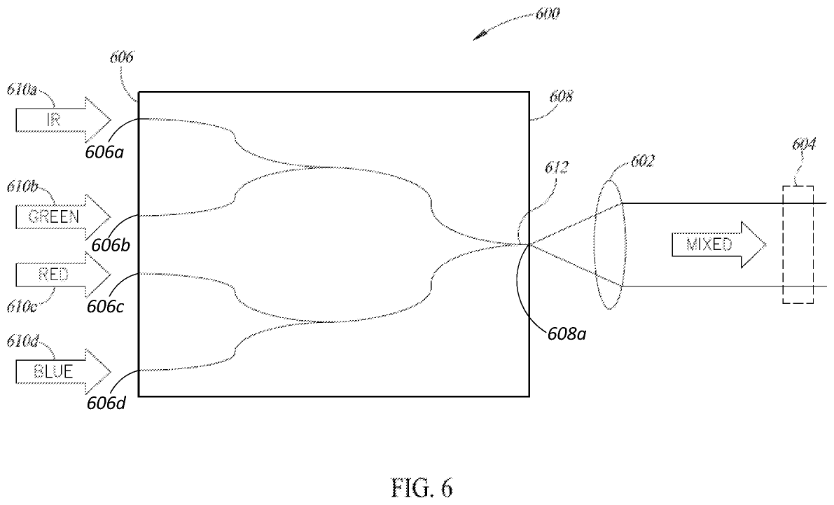

One or more implementations of the present disclosure provide laser-based optical engines, for example, laser-based optical engines for laser projectors used in wearable heads-up displays or other applications. Generally, the optical engines discussed herein integrate a plurality of laser dies or diodes (e.g., 3 laser diodes, 4 laser diodes) within a single, hermetically sealed or partially hermetically sealed, encapsulated package. As discussed further below with reference to FIGS. 6, 7, 8, 9, and 10, in at least some implementations, photonic integrated circuits may be used to wavelength multiplex beams of light emitted by the plurality of laser diodes into a coaxially superimposed aggregate beam. Alternatively, each wavelength of light may be channeled individually through the photonic integrated circuit. Such optical engines may have various advantages over existing designs including, for example, smaller volume, lower weight, better manufacturability, lower cost, faster modulation speed, etc. The material used for the optical engines discussed herein may be any suitable materials, e.g., ceramics with advantageous thermal properties, etc. As noted above, such features are particularly advantages in various applications including WHUDs.

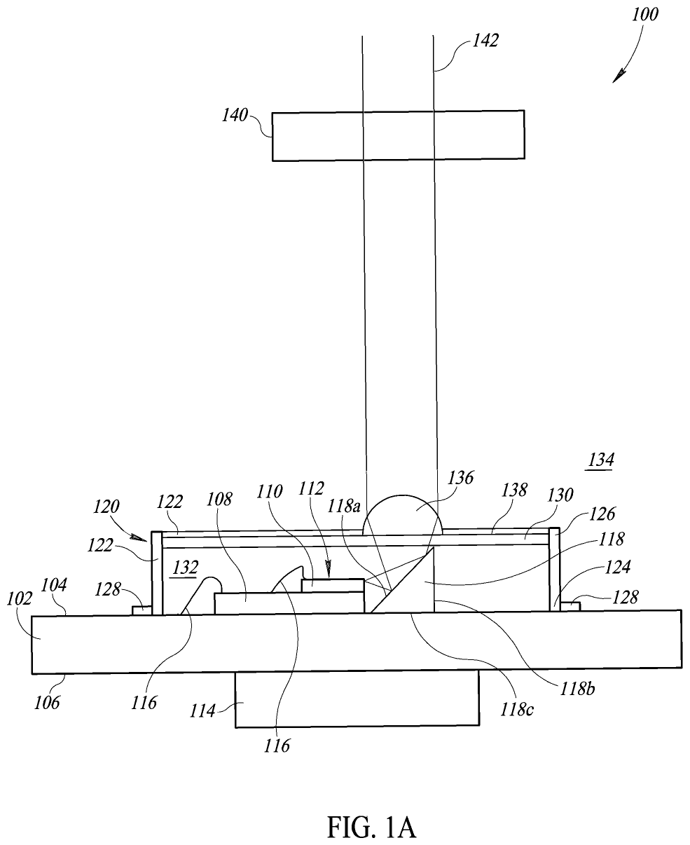

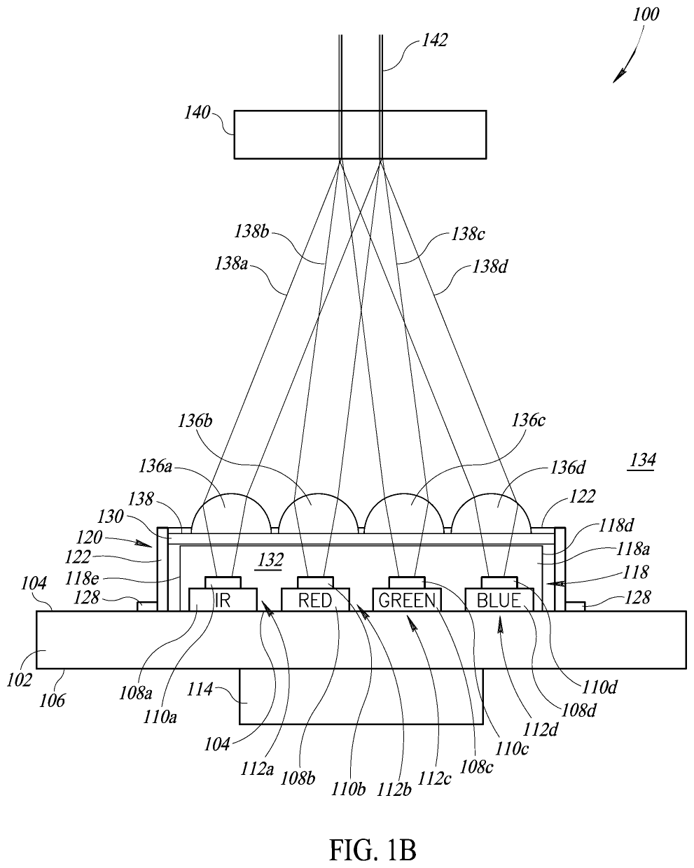

FIG. 1A is a left side, elevational sectional view of an optical engine 100, which may also be referred to as a “multi-laser diode module” or an “RGB laser module,” in accordance with the present systems, devices, and methods. FIG. 1B is a front side, elevational sectional view of the optical engine 100. The optical engine 100 includes a base substrate 102 having a top surface 104 and a bottom surface 106 opposite the top surface. The base substrate 102 may be formed from a material that is radio frequency (RF) compatible and is suitable for hermetic sealing. For example, the base substrate 102 may be formed from low temperature co-fired ceramic (LTCC), alumina, aluminum nitride (AlN), Kovar®, other ceramics with suitable thermal properties, etc. The term Kovar® generally refers to iron-nickel-cobalt alloys having similar thermal expansion coefficients to glass and ceramics, thus making Kovar® materials particularly suitable for forming hermetic seals which remain functional in a wide range of temperatures.

The optical engine 100 also includes a plurality of chip submounts 108a-108d (collectively 108) bonded (e.g., attached) to the top surface 104 of the base substrate 102. The plurality of chip submounts 108 are aligned in a row across a width of the optical engine 100 between the left and right sides thereof. Each of the plurality of chip submounts 108 includes a laser diode 110, also referred to as a laser chip or laser die, bonded thereto. In particular, an infrared chip submount 108a carries an infrared laser diode 110a, a red chip submount 108b carries a red laser diode 110b, a green chip submount 108c carries a green laser diode 110c, and a blue chip submount 108d carries a blue laser diode 110d. In operation, the infrared laser diode 110a provides infrared laser light, the red laser diode 110b provides red laser light, the green laser diode 110c provides green laser light, and the blue laser diode 110d provides blue laser light. Each of the laser diodes 110 may comprise one of an edge emitter laser or a vertical-cavity surface-emitting laser (VCSEL), for example. Each of the four laser diode/chip submount pairs may be referred to collectively as a “laser chip on submount,” or a laser CoS 112. Thus, the optical engine 100 includes an infrared laser CoS 112a, a red laser CoS 112b, a green laser CoS 112c, and a blue laser CoS 112d. In at least some implementations, one or more of the laser diodes 110 may be bonded directly to the base substrate 102 without use of a submount 108. It should be appreciated that although some implementations discussed herein describe laser diodes as chips or dies on submounts, other dies or types of devices, e.g., p-side down devices, may be used as well.

The optical engine 100 also includes a laser diode driver circuit 114 bonded to the bottom surface 106 of the base substrate 102. The laser diode driver circuit 114 is operatively coupled to the plurality of laser diodes 110 via suitable electrical connections 116 to selectively drive current to the plurality of laser diodes. In at least some implementations, the laser diode driver circuit 114 may be positioned relative to the CoSs 112 to minimize the distance between the laser diode driver circuit 114 and the CoSs 112. Although not shown in FIGS. 1A and 1B, the laser diode driver circuit 114 may be operatively coupleable to a controller (e.g., microcontroller, microprocessor, ASIC) which controls the operation of the laser diode driver circuit 114 to selectively modulate laser light emitted by the laser diodes 110. In at least some implementations, the laser diode driver circuit 114 may be bonded to another portion of the base substrate 102, such as the top surface 104 of the base substrate. In at least some implementations, the laser diode driver circuitry 114 may be remotely located and operatively coupled to the laser diodes 110. In order to not require the use of impedance matched transmission lines, the size scale may be small compared to a wavelength (e.g., lumped element regime), where the electrical characteristics are described by (lumped) elements like resistance, inductance, and capacitance.

Proximate the laser diodes 110 there is positioned an optical director element 118. Like the chip submounts 108, the optical director element 118 is bonded to the top surface 104 of the base substrate 102. In the illustrated example, the optical director element 118 has a triangular prism shape that includes a plurality of planar faces. In particular the optical director element 118 includes an angled front face 118a that extends along the width of the optical engine 100, a rear face 118b, a bottom face 118c that is bonded to the top surface 104 of the base substrate 102, a left face 118d, and a right face 118e opposite the left face. The optical director element 118 may comprise a mirror or a prism, for example.

The optical engine 100 also includes a cap 120 that includes a vertical sidewall 122 having a lower first end 124 and an upper second end 126 opposite the first end. A flange 128 may be disposed around a perimeter of the sidewall 122 adjacent the lower first end 124. Proximate the upper second end 126 of the sidewall 122 there is a horizontal optical window 130 that forms the “top” of the cap 120. The sidewall 122 and the optical window 130 together define an interior volume 132 sized and dimensioned to receive the plurality of chip submounts 108, the plurality of laser diodes 110, and the optical director element 118. The lower first end 124 and the flange 128 of the cap 120 are bonded to the base substrate 102 to provide a hermetic seal or a partial hermetic seal between the interior volume 132 of the cap and a volume 134 exterior to the cap.

As shown best in FIG. 1A, the optical director element 118 is positioned and oriented to direct (e.g., reflect) laser light received from each of the plurality of laser diodes 108 upward (as shown) toward the optical window 130 of the cap 120, wherein the laser light exits the interior volume 132.

The cap 120 may have a round shape, rectangular shape, or other shape. Thus, the vertical sidewall 122 may comprise a continuously curved sidewall, a plurality (e.g., four) of adjacent planar portions, etc. The optical window 130 may comprise an entire top of the cap 120, or may comprise only a portion thereof. In at least some implementations, the optical window 130 may be located on the sidewall 122 rather than positioned as a top of the cap 120, and the laser diodes 110 and/or the optical director element 118 may be positioned and oriented to direct the laser light from the laser diodes toward the optical window on the sidewall 122. At least some implementations may not include optical director element 118 such that laser light from the laser diodes may be output towards the optical window on the sidewall 122 without the need for intervening optical elements. In at least some implementations, the cap 120 may include a plurality of optical windows instead of a single optical window.

The optical engine 100 also includes four collimation/pointing lenses 136a-136d (collectively 136), one for each of the four laser diodes 110a-110d, respectively, that are bonded to a top surface 138 of the optical window 130. Each of the plurality of collimation lenses 136 is positioned and oriented to receive light from a corresponding one of the laser diodes 110 through the optical window 130. In particular, the collimation lens 136a receives light from the infrared laser diode 110a via the optical director element 118 and the optical window 130, the collimation lens 136b receives light from the red laser diode 110b via the optical director element and the optical window, the collimation lens 136c receives light from the green laser diode 110c via the optical director element and the optical window, and the collimation lens 136d receives light from the blue laser diode 110d via the optical director element and the optical window.

Each of the collimation lenses 136 is operative to receive laser light from a respective one of the laser diodes 110, and to generate a single color beam. In particular, the collimation lens 136a receives infrared laser light from the infrared laser diode 110a and produces an infrared laser beam 138a, the collimation lens 136b receives red laser light from the red laser diode 110b and produces a red laser beam 138b, the collimation lens 136c receives green laser light from the green laser diode 110c and produces a green laser beam 138c, and the collimation lens 136d receives blue laser light from the blue laser diode 110d and produces a blue laser beam 138d.

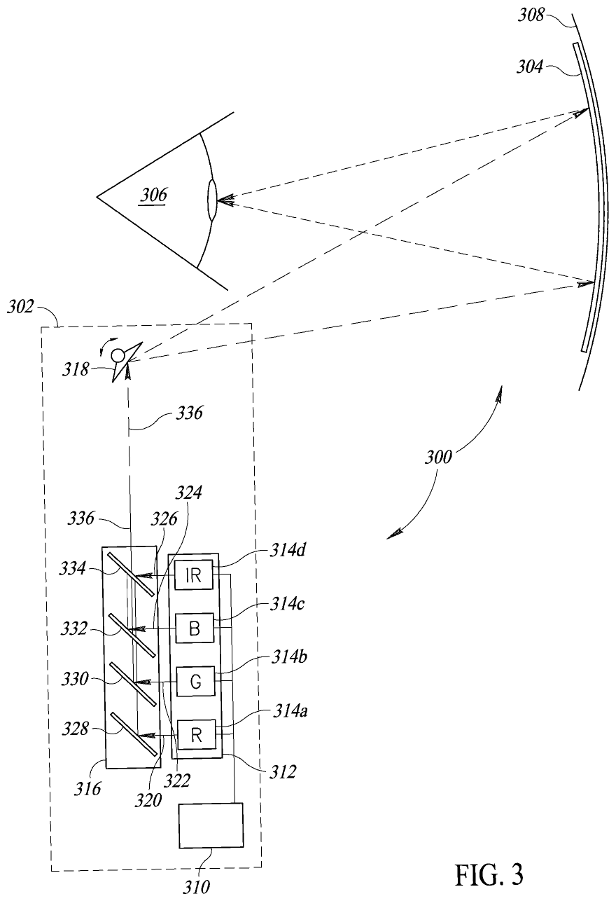

The optical engine 100 may also include, or may be positioned proximate to, a beam combiner 140 that is positioned and oriented to combine the light beams 138a-138d received from each of the collimation lenses 136 into a single aggregate beam 142. As an example, the beam combiner 140 may include one or more diffractive optical elements (DOE) and/or refractive/reflective optical elements that combine the different color beams 138a-138d in order to achieve coaxial superposition. An example beam combiner is shown in FIG. 3 and discussed below.

In at least some implementations, the laser CoSs 112, the optical director element 118, and/or the collimation lenses 136 may be positioned differently. As noted above, laser diode driver circuit 114 may be mounted on the top surface 104 or the bottom surface 106 of the base substrate 102, depending on the RF design and other constraints (e.g., package size). In at least some implementations, the optical engine 100 may not include the optical director element 118, and the laser light may be directed from the laser diodes 110 toward the collimation lenses 136 without requiring an intermediate optical director element. Additionally, in at least some implementations, one or more of the laser diodes may be mounted directly on the base substrate 102 without use of a submount.

For the sake of a controlled atmosphere inside the interior volume 132, it may be desirable to have no organic compounds inside the interior volume 132. In at least some implementations, the components of the optical engine 100 may be bonded together using no adhesives. In other implementations, a low amount of adhesives may be used to bond at least one of the components, which may reduce cost while providing a relatively low risk of organic contamination for a determined lifetime (e.g., 2 or more years) of the optical engine 100. The use of adhesives may result in a partial hermetic seal, but this partial hermetic seal may be acceptable in certain applications, as detailed below.

Generally, “hermetic” refers to a seal which is airtight, that is, a seal which excludes the passage of air, oxygen, and other gases. “Hermetic” within the present specification carries this meaning. Further, “partially hermetic” as used herein refers to a seal which limits, but does not necessarily completely prevent, the passage of gases such as air. “Partially hermetic” as used herein may alternatively be stated as “reduced hermiticity”. In the example above, adhesives may be used to bond components. Such adhesives may result in a seal being not completely hermetic, in that some amount of gasses may slowly leak through the adhesive. However, such a seal can still be considered “partially hermetic” or as having “reduced hermiticity”, because the seal reduces the flow of gasses therethrough.

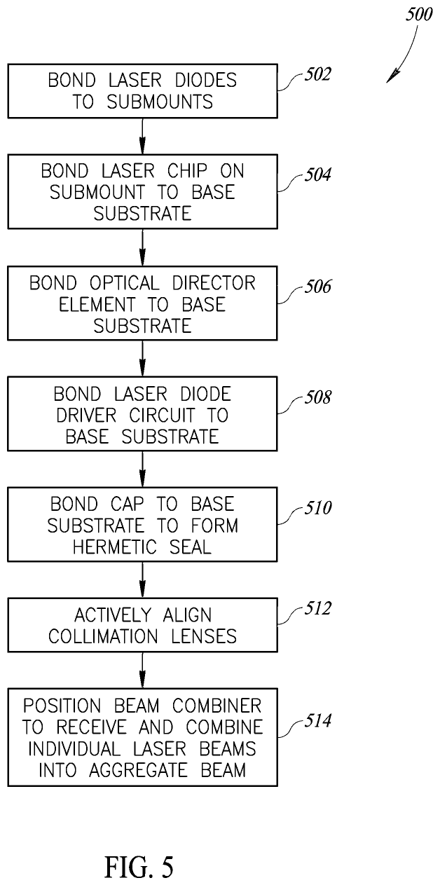

In one example application, even in an environment with only partial hermiticity, the life of laser diodes 110 and transparency of optical window 130 may be maintained longer than the life of a battery of a device, such that partial hermiticity may be acceptable for the devices. In some cases, even protecting interior volume 132 from particulate with a dust cover may be sufficient to maintain laser diodes 110 and transparency of optical window 130 for the intended lifespan of the device. In some cases, laser diodes 110 and transparency of optical window 130 may last for the intended lifespan of the device even without a protective cover. Various bonding processes (e.g., attaching processes) for the optical engine 100 are discussed below with reference to FIG. 5.

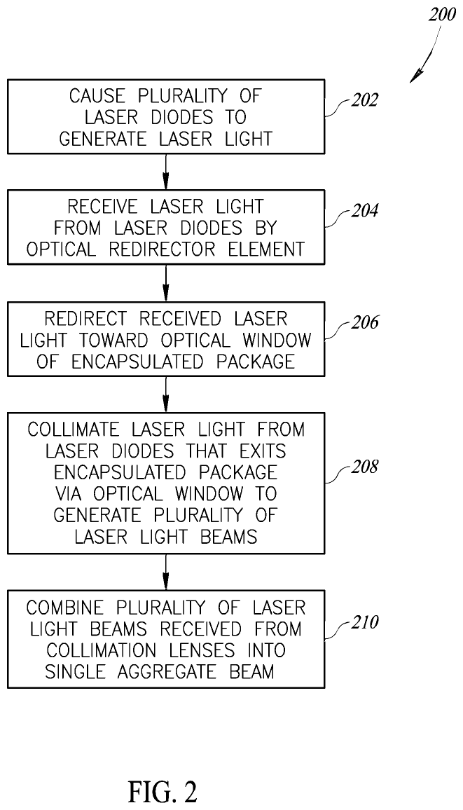

FIG. 2 is a flow diagram of a method 200 of operating an optical engine, in accordance with the present systems, devices, and methods. The method 200 may be implemented using the optical engine 100 of FIGS. 1A-1B, for example. It should be appreciated that methods of operating optical engines according to the present disclosure may include fewer or additional acts than set forth in the method 200. Further, the acts discussed below may be performed in an order different than the order presented herein.

At 202, at least one controller may cause a plurality of laser diodes of an optical engine to generate laser light. As discussed above, the plurality of laser diodes may be hermetically sealed or partially hermetically sealed in an encapsulated package. The laser diodes may produce light sequentially and/or simultaneously with each other. At 204, at least one optical director element may optionally receive the laser light from the laser diodes. The optical director element may comprise a mirror or a prism, for example. As discussed above, in at least some implementations the optical engine may be designed such that laser light exits the optical engine without use of an optical director element.

At 206, the at least one optical director element, if included, may direct the received laser light toward an optical window of the encapsulated package. For example, the optical director element may reflect the received laser light toward the optical window of the encapsulated package. In implementations without at least one optical director element, the laser light generated by the plurality of laser diodes may be output directly toward the optical window of the encapsulated package.

At 208, a plurality of collimation lenses may collimate the laser light from the laser diodes that exits the encapsulated package via the optical window to generate a plurality of differently colored laser light beams. The collimation lenses may be positioned inside or outside of the encapsulated package. As an example, the collimation lenses may be physically coupled to the optical window of the encapsulated package.

At 210, a beam combiner may combine the plurality of laser light beams received from each of the collimation lenses into a single aggregate beam. The beam combiner may include one or more diffractive optical elements (DOE) that combine different color beams in order to achieve coaxial superposition, for example. The beam combiner may include one or more DOEs and/or one or more refractive/reflective optical elements. An example beam combiner is shown in FIG. 3 and discussed below.

FIG. 3 is a schematic diagram of a wearable heads-up display (WHUD) 300 with an exemplary laser projector 302, and a transparent combiner 304 in a field of view of an eye 306 of a user of the WHUD, in accordance with the present systems, devices, and methods. The WHUD 300 includes a support structure (not shown), with the general shape and appearance of an eyeglasses frame, carrying an eyeglass lens 308 with the transparent combiner 304, and the laser projector 302.

The laser projector 302 comprises a controller or processor 310, an optical engine 312 comprising four laser diodes 314a, 314b, 314c, 314d (collectively 314) communicatively coupled to the processor 310, a beam combiner 316, and a scan mirror 318. The optical engine 312 may be similar or identical to the optical engine 100 discussed above with reference to FIGS. 1A and 1B. Generally, the term “processor” refers to hardware circuitry, and may include any of microprocessors, microcontrollers, application specific integrated circuits (ASICs), digital signal processors (DSPs), programmable gate arrays (PGAs), and/or programmable logic controllers (PLCs), or any other integrated or non-integrated circuit.

During operation of the WHUD 300, the processor 310 modulates light output from the laser diodes 314, which includes a first red laser diode 314a (R), a second green laser diode 314b (G), a third blue laser diode 314c (B), and a fourth infrared laser diode 314d (IR). The first laser diode 314a emits a first (e.g., red) light signal 320, the second laser diode 314b emits a second (e.g., green) light signal 322, the third laser diode 314c emits a third (e.g., blue) light signal 324, and the fourth laser diode 314d emits a fourth (e.g., infrared) light signal 326. All four of light signals 320, 322, 324, and 326 enter or impinge on the beam combiner 316. Beam combiner 316 could for example be based on any of the beam combiners described in U.S. Provisional Patent Application Ser. No. 62/438,725, U.S. Non-Provisional patent application Ser. No. 15/848,265 (U.S. Publication Number 2018/0180885), U.S. Non-Provisional patent application Ser. No. 15/848,388 (U.S. Publication Number 2018/0180886), U.S. Provisional Patent Application Ser. No. 62/450,218, U.S. Non-Provisional patent application Ser. No. 15/852,188 (U.S. Publication Number 2018/0210215), U.S. Non-Provisional patent application Ser. No. 15/852,282, (U.S. Publication Number 2018/0210213), and/or U.S. Non-Provisional patent application Ser. No. 15/852,205 (U.S. Publication Number 2018/0210216).

In the illustrated example, the beam combiner 316 includes optical elements 328, 330, 332, and 334. The first light signal 320 is emitted towards the first optical element 328 and reflected by the first optical element 328 of the beam combiner 316 towards the second optical element 330 of the beam combiner 316. The second light signal 322 is also directed towards the second optical element 330. The second optical element 330 is formed of a dichroic material that is transmissive of the red wavelength of the first light signal 320 and reflective of the green wavelength of the second light signal 322. Therefore, the second optical element 330 transmits the first light signal 320 and reflects the second light signal 322. The second optical element 330 combines the first light signal 320 and the second light signal 322 into a single aggregate beam (shown as separate beams for illustrative purposes) and routes the aggregate beam towards the third optical element 332 of the beam combiner 316.

The third light signal 324 is also routed towards the third optical element 332. The third optical element 332 is formed of a dichroic material that is transmissive of the wavelengths of light (e.g., red and green) in the aggregate beam comprising the first light signal 320 and the second light signal 322 and reflective of the blue wavelength of the third light signal 324. Accordingly, the third optical element 332 transmits the aggregate beam comprising the first light signal 320 and the second light signal 322 and reflects the third light signal 324. In this way, the third optical element 332 adds the third light signal 324 to the aggregate beam such that the aggregate beam comprises the light signals 320, 322, and 324 (shown as separate beams for illustrative purposes) and routes the aggregate beam towards the fourth optical element 334 in the beam combiner 316.

The fourth light signal 326 is also routed towards the fourth optical element 334. The fourth optical element 334 is formed of a dichroic material that is transmissive of the visible wavelengths of light (e.g., red, green, and blue) in the aggregate beam comprising the first light signal 320, the second light signal 322, and the third light signal 324 and reflective of the infrared wavelength of the fourth light signal 326. Accordingly, the fourth optical element 334 transmits the aggregate beam comprising the first light signal 320, the second light signal 322, and the third light signal 324 and reflects the fourth light signal 326. In this way, the fourth optical element 334 adds the fourth light signal 326 to the aggregate beam such that the aggregate beam 336 comprises portions of the light signals 320, 322, 324, and 326. The fourth optical element 334 routes the aggregate beam 336 towards the controllable scan mirror 318.

The scan mirror 318 is controllably orientable and scans (e.g. raster scans) the beam 336 to the eye 306 of the user of the WHUD 300. In particular, the controllable scan mirror 318 scans the laser light onto the transparent combiner 304 carried by the eyeglass lens 308. The scan mirror 318 may be a single bi-axial scan mirror or two single-axis scan mirrors may be used to scan the laser light onto the transparent combiner 304, for example. In at least some implementations, the transparent combiner 304 may be a holographic combiner with at least one holographic optical element. The transparent combiner 304 redirects the laser light towards a field of view of the eye 306 of the user. The laser light redirected towards the eye 306 of the user may be collimated by the transparent combiner 304, wherein the spot at the transparent combiner 304 is approximately the same size and shape as the spot at the eye 306 of the user. The laser light may be converged by the eye 306 to a focal point at the retina of eye 306 and creates an image that is focused. The visible light may create display content in the field of view of the user, and the infrared light may illuminate the eye 306 of the user for the purpose of eye tracking.

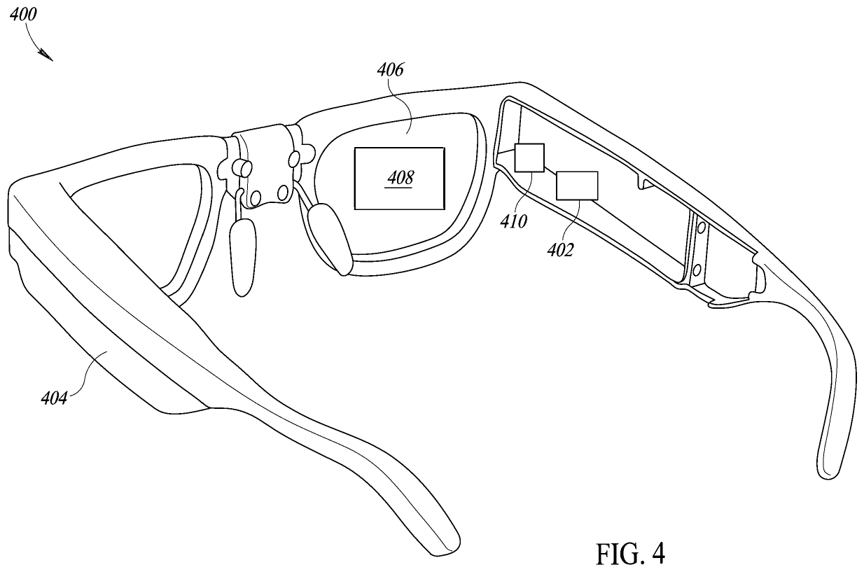

FIG. 4 is a schematic diagram of a wearable heads-up display (WHUD) 400 with a laser projector 402 in accordance with the present systems, devices, and methods. WHUD 400 includes a support structure 404 with the shape and appearance of a pair of eyeglasses that in use is worn on the head of the user. The support structure 404 carries multiple components, including eyeglass lens 406, a transparent combiner 408, the laser projector 402, and a controller or processor 410. The laser projector 402 may be similar or identical to the laser projector 302 of FIG. 3. For example, the laser projector 402 may include an optical engine, such as the optical engine 100 or the optical engine 312. The laser projector 402 may be communicatively coupled to the controller 410 (e.g., microprocessor) which controls the operation of the projector 402, as discussed above. The controller 410 may include or may be communicatively coupled to a non-transitory processor-readable storage medium (e.g., memory circuits such as ROM, RAM, FLASH, EEPROM, memory registers, magnetic disks, optical disks, other storage), and the controller may execute data and/or instruction from the non-transitory processor readable storage medium to control the operation of the laser projector 402.

In operation of the WHUD 400, the controller 410 controls the laser projector 402 to emit laser light. As discussed above with reference to FIG. 3, the laser projector 402 generates and directs an aggregate beam (e.g., aggregate beam 336 of FIG. 3) toward the transparent combiner 408 via at least one controllable mirror (not shown in FIG. 4). The aggregate beam is directed towards a field of view of an eye of a user by the transparent combiner 408. The transparent combiner 408 may collimate the aggregate beam such that the spot of the laser light incident on the eye of the user is at least approximately the same size and shape as the spot at transparent combiner 408. The transparent combiner 408 may be a holographic combiner that includes at least one holographic optical element.

FIG. 5 is a flow diagram of a method 500 of manufacturing an optical engine, in accordance with the present systems, devices, and methods. The method 500 may be implemented to manufacture the optical engine 100 of FIGS. 1A-1B or the optical engine 312 of FIG. 3, for example. It should be appreciated that methods of manufacturing optical engines according to the present disclosure may include fewer or additional acts than set forth in the method 500. Further, the acts discussed below may be performed in an order different than the order presented herein.

At 502, a plurality of laser diodes may be bonded to a respective plurality of submounts. In at least some implementations, this method may be performed by an entity different than that manufacturing the optical engine. For example, in at least some implementations, one or more of the plurality of laser diodes (e.g., green laser diode, blue laser diode) may be purchased as already assembled laser CoSs. For ease of handling and simplification of the overall process, in at least some implementations it may be advantageous to also bond laser diodes that cannot be procured on submounts to a submount as well. As a non-limiting example, in at least some implementations, one or more of the laser diodes may be bonded to a corresponding submount using an eutectic gold tin (AuSn) solder process, which is flux-free and requires heating up top 280° C.

At 504, the plurality of CoSs may be bonded to a base substrate. Alternatively, act 502 could be skipped for at least one or all of the laser diodes, and act 504 could comprise bonding the at least one or all of the laser diodes directly to the base substrate. The base substrate may be formed from a material that is RF compatible and is suitable for hermetic sealing. For example, the base substrate may be formed from low temperature co-fired ceramic (LTCC), aluminum nitride (AlN), alumina, Kovar®, etc. Since several CoSs are bonded next to each other on the same base substrate, it may be advantageous to either “step-solder” them sequentially or to use a bonding technique that does not rely on re-melting of solder materials. For step-soldering, each subsequent soldering step utilizes a process temperature that is less than the process temperatures of previous solder steps to prevent re-melting of solder materials. It may also be important that the laser diode-to-submount bonding does not re-melt during bonding of the CoSs to the base substrate. Bonding technologies other than step-soldering that may be used include parallel soldering of all CoS in reflow oven process, thermosonic or thermocompression bonding, transient liquid phase (TLP) bonding, laser soldering, etc. Some of these example bonding technologies are discussed below.

For parallel soldering of all CoSs in a reflow oven process, appropriate tooling is required to assure proper bonding and alignment during the process. An advantage of this process is the parallel and hence time efficient bonding of all CoSs at once and even many assemblies in parallel. A possible disadvantage of this process is the potential loss of the alignment of components during the reflow process. Generally, a soldering cycle ideally needs a few minutes of dwell time. Preheating may be used to reduce the soldering time, which requires a few minutes for such a process depending on the thermal mass of the components being bonded. Thus, a batch process may be used with regular soldering to reduce the assembly costs with high throughput at the expense of alignment tolerance.

For thermosonic or thermocompression bonding, thick gold metallization may be used but no extra solder layer is required. The temperatures for thermocompression bonding might be as high as 300 to 350° C. to have a good bond with a good thermal conductivity. Thermosonic bonding may be used to reduce the pressure and temperature needed for bonding, which may be required for at least some components that might not tolerate the temperatures required for thermocompression bonding.

Transient liquid phase (TLP) bonding may also be used. There are many different reaction couples that may be used, including gold-tin, copper-tin, etc. With this method, a liquid phase is formed during the bonding which will solidify at the same temperature. The re-melting temperatures of the bond are much higher than the soldering temperatures.

In at least some implementations, laser soldering may be used to bond some or all of the components of the optical engine. Generally, the thermal characteristic of the parts to be bonded may be important when implementing a laser soldering process.

Subsequent reflows of solder are not recommended due to liquid phase reaction or dissolution mechanisms which may reduce the reliability of the joint. This could result in voiding at the interface or a reduction in strength of the joint itself. In order to mitigate potential reflow dissolution problems, other options can be taken into consideration, which do not rely on extreme heating of the device and can be favorable in terms of production cost. For example, bonding of the base substrate with adhesives (electrically conductive for common mass, or non-conductive for floating) may be acceptable with respect to heat transfer and out-gassing as discussed regarding partial hermetic sealing above.

Further, in at least some implementations, a reactive multi-layer foil material (e.g., NanoFoil®) or a similar material may be used as a solder pre-form, which enables localized heat transfer. A reactive multi-layer foil material is a metallic material based on a plurality (e.g., hundreds, thousands) of reactive foils (aluminum and nickel) that enables die-attach soldering (e.g., silicon chip onto stainless steel part). In such implementations, dedicated heat transfer support metallizations may be deposited onto the two components being joined together. This method may be more advantageous for CoS-to-base substrate mounting compared to chip-to-submount bonding. Generally, bonding using reactive multi-layer foil materials enables furnace-free, low-temperature soldering of transparent or non-transparent components, without reaching the bonding temperatures for solder reflow processes. Reactive multi-layer foil materials can be patterned with a ps-laser into exact preform shapes.

At 506, the optical director element, if included, may be bonded to the base substrate proximate the laser CoSs. The optical director element may be bonded to the base substrate using any suitable bonding process, including the bonding processes discussed above with reference to act 504.

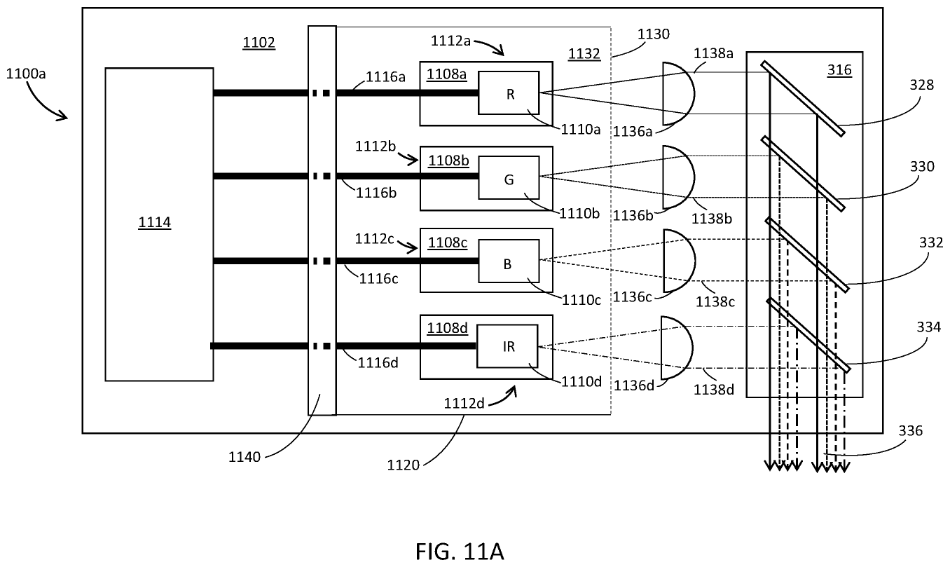

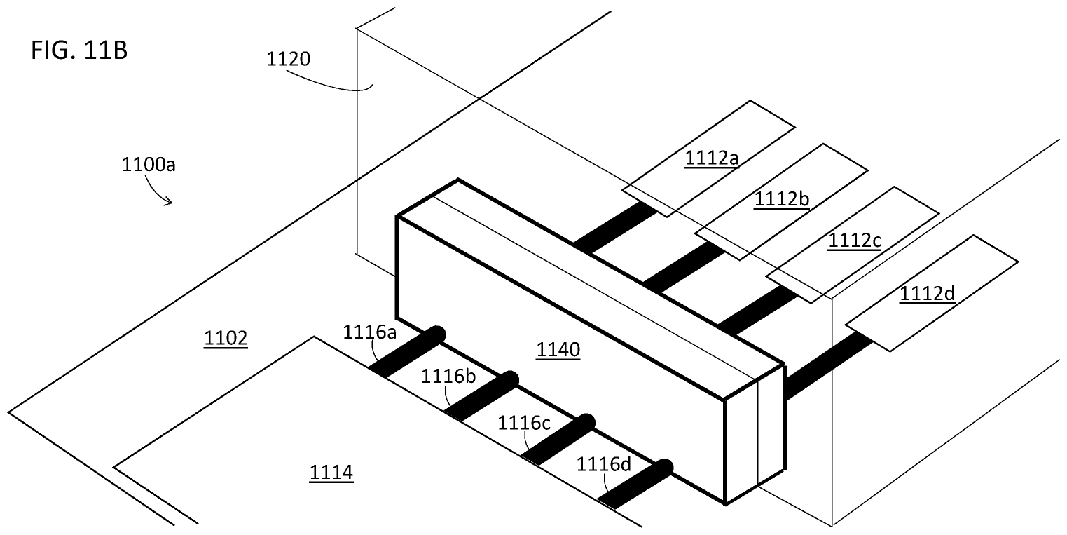

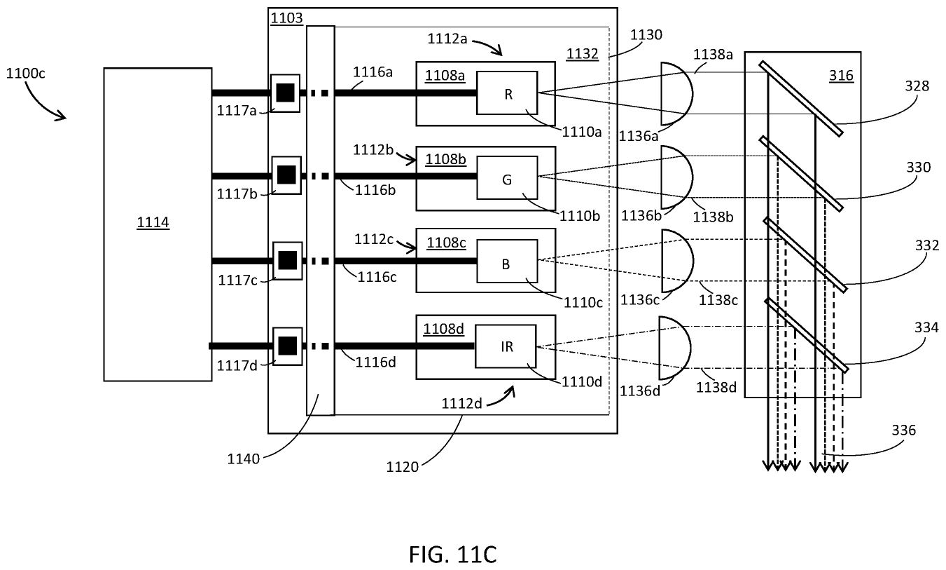

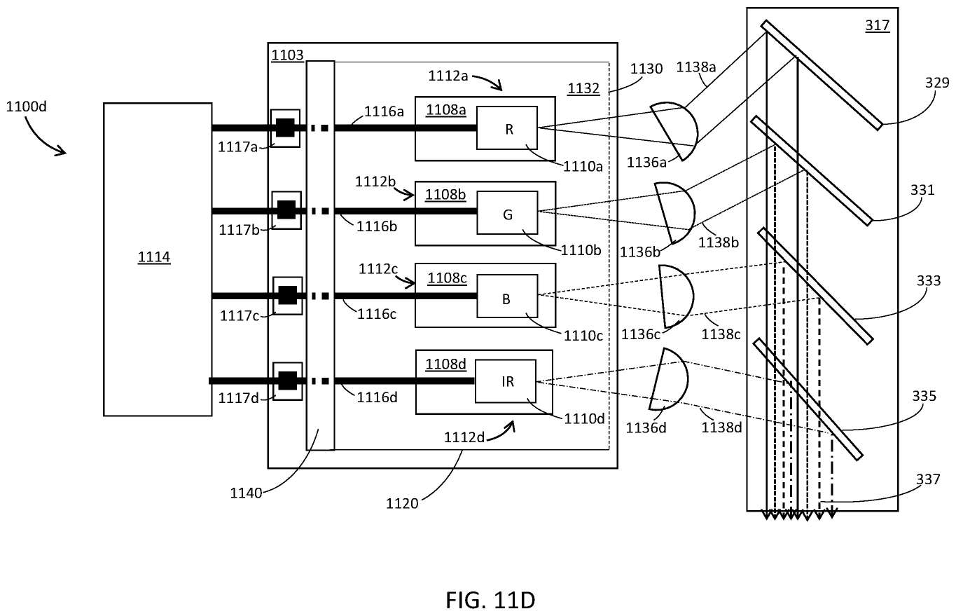

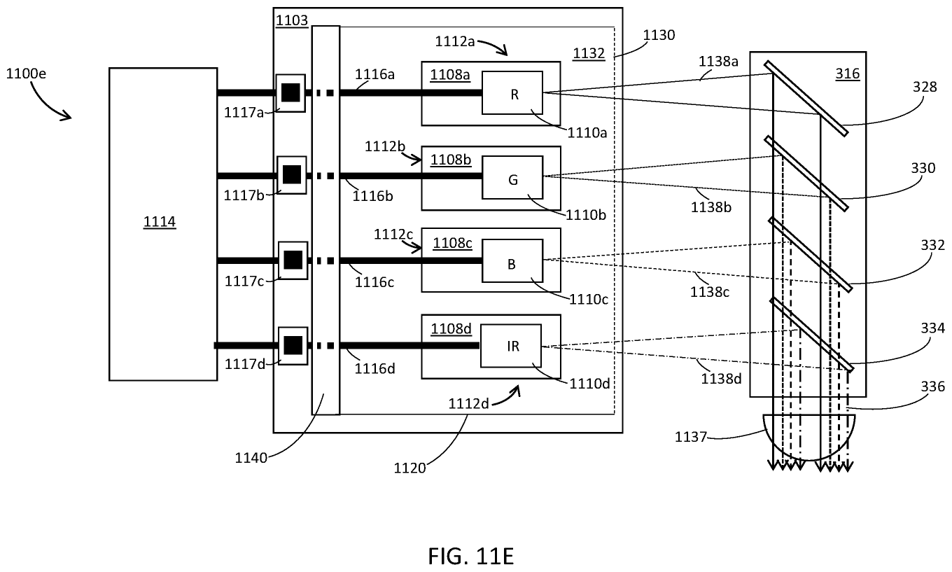

At 508, the laser diode driver circuit may optionally be bonded to the base substrate. As noted above, the laser diode driver circuit may be bonded to the base substrate such that the distance between the laser diode driver circuit and the laser CoSs is minimized. This may also comprise positioning a plurality of electrical connections which operatively couple the laser diode driver circuit to the plurality of laser diodes as shown in FIGS. 11A-11E. In alternative implementations, the laser diode driver circuit may be bonded to a separate base substrate from the other components mentioned above as shown in FIGS. 11C-11E. The process used to bond the laser diode driver circuit to the base substrate may be any suitable bonding process, such as bonding processes commonly used to bond surface mount devices (SMD) to circuit boards. In other alternative implementations, the laser diode driver circuit may be mounted directly to a frame of a WHUD. For implementations where the laser diode drive circuit is not bonded to the same base substrate as the other components mentioned above, a plurality of electrical contacts and electrical connections could be bonded to the base substrate, each electrical connection operatively connecting a respective electrical contact to a respective laser diode. Subsequently, the at least one laser driver circuit could be operatively coupled to the electrical contacts, which will then electrically couple the laser diode drive circuit to the electrical connections and consequently to the laser diodes. Exemplary arrangements of electrical connections and electrical contacts is discussed later with reference to FIGS. 11C-11E.

At 510, the cap may be bonded to the base substrate to form a hermetic seal or a partial hermetic seal as discussed above between the interior volume of the encapsulated package and an exterior environment. As noted above, it may be desirable to maintain a specific atmosphere for the laser diode chips for reliability reasons. In at least some implementations, adhesive sealing may be undesirable because of the high permeability of gases. This is especially the case for blue laser diodes, which emit blue laser light that may bake contamination on facets and windows, thereby reducing transparency of the optical window. However, as detailed above regarding FIGS. 1A and 1B, partial hermeticity, a particulate dust cover, or even no protective cover may be acceptable for certain applications. In implementations where the cap would be bonded over electrical connections which connect the at least one laser diode driver circuit to the plurality of laser diodes, such as when the at least one laser diode driver circuit is bonded to the same side of a base substrate as the laser diodes, or when the at least one laser diode driver circuit is coupled to electrical contacts bonded to the same side of the base substrate as the laser diodes, an electrically insulating cover can first be bonded to the base substrate over the electrical connections. Subsequently, the cap can be bonded at least partially to the electrically insulating cover, and potentially to a portion of the base substrate if the insulating cover does not fully encircle the intended interior volume. In this way, at least a portion of the cap will be bonded to the base substrate indirectly by being bonded to the electrically insulating cover. In some implementations, the entire cap could be bonded to the base substrate indirectly by being bonded to an electrically insulating cover which encircles the intended interior volume. Exemplary electrically insulating covers are discussed later with reference to FIGS. 11A-11E.

During the sealing process, the atmosphere may be defined by flooding the package accordingly. For example, the interior volume of the encapsulated package may be flooded with an oxygen enriched atmosphere that burns off contaminants which tend to form on interfaces where the laser beam is present. The sealing itself may also be performed so as to prevent the exchange between the package atmosphere and the environment. Due to limitations concerning the allowed sealing temperature, e.g., the components inside the package should not be influenced, in at least some implementations seam welding or laser assisted soldering/diffusion bonding may be used. In at least some implementations, localized sealing using a combination of seam welding and laser soldering may be used.

At 512, the collimation lenses may be actively aligned. For example, once the laser diode driver circuit has been bonded and the cap has been sealed, the laser diodes can be turned on and the collimations lenses for each laser diode can be actively aligned. In at least some implementations, each of the collimation lenses may be positioned to optimize spot as well as pointing for each of the respective laser diodes.

At 514, the beam combiner may be positioned to receive and combine individual laser beams into an aggregate beam. As discussed above, the beam combiner may include one or more diffractive optical elements and/or one or more refractive/reflective optical elements that function to combine the different color beams into an aggregate beam. The aggregate beam may be provided to other components or modules, such as a scan mirror of a laser projector, etc.

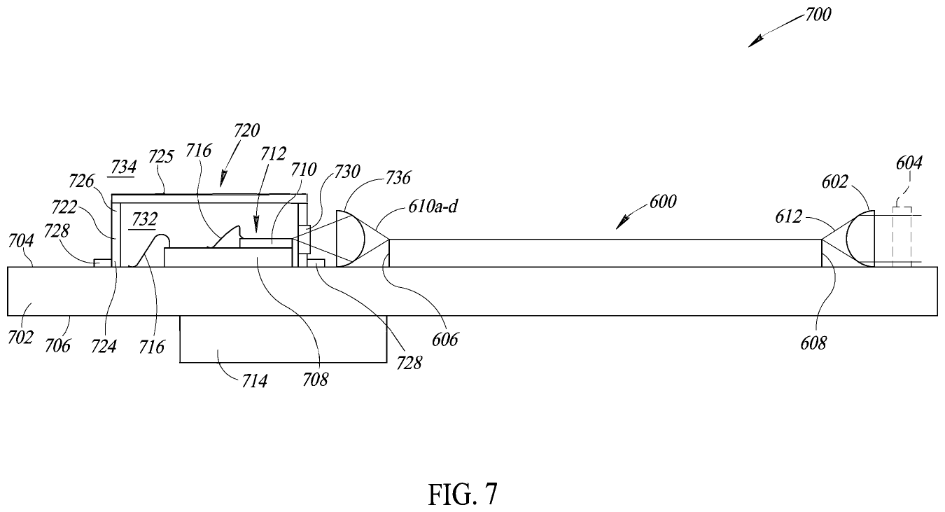

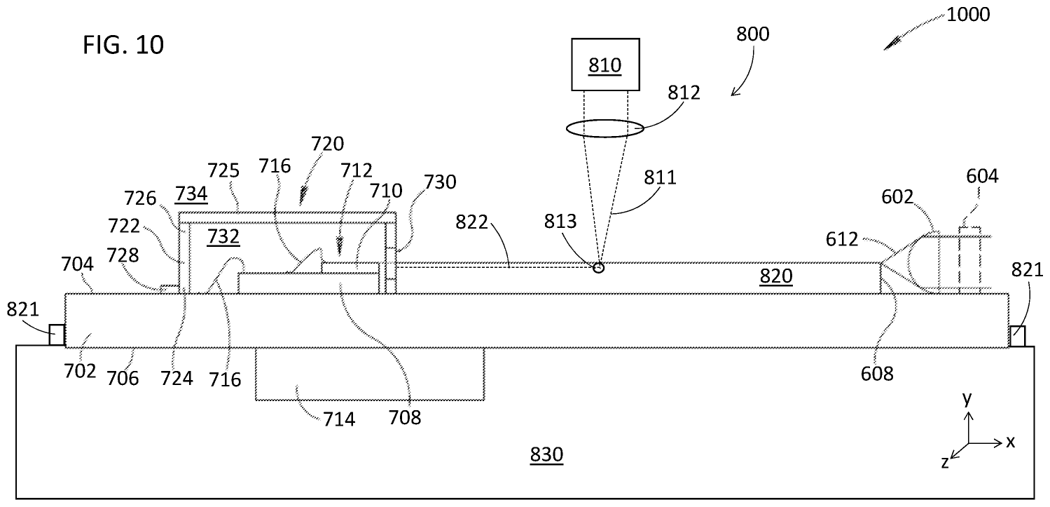

FIG. 6 is a top plan view of a photonic integrated circuit 600 for wavelength multiplexing followed by a common collimation lens 602 and an optional diffractive optical element 604. The photonic integrated circuit 600 may be a component in an optical engine, such as an optical engine 700 of FIG. 7 or an optical engine of FIG. 10 discussed further below. The photonic integrated circuit 600 includes at least one input optical edge 606 having at least one input facet and at least one output optical edge 608 having at least one output facet. In the example of FIG. 6, input edge 606 includes four input facets 606a, 606b, 606c, and 606d, whereas output edge 608 includes one output facet 608a. However, it is within the scope of the present systems, devices, and methods to include any appropriate number of input facets and output facets. In operation, the photonic integrated circuit 600 receives a plurality of beams of light 610a-610d that are edge coupled to the photonic integrated circuit at the input optical edge 606 by respective input facets 608a-608d, and wavelength multiplexes the plurality of beams to provide a coaxially superimposed aggregate beam of light 612 that exits the photonic integrated circuit at the output optical edge 608 through output facet 608a. Generally, the photonic integrated circuit 600 may include one or more diffractive optical elements (DOE) and/or refractive/reflective optical elements that combine the different color beams 610a-d in order to achieve coaxial superposition.

Following out-coupling of the aggregate beam 612 from the output optical edge 608 of the photonic integrated circuit 600, the aggregated beam is collimated via the common collimation lens 602. In at least some implementations, the collimation lens 602 may be either an achromatic lens or an apochromatic lens (or lens assemblies), depending on the particular optical design and tolerances of the system. In at least some implementations, one or more diffractive optical elements 604 may be used to provide wavelength dependent focus correction.

FIG. 7 is a left side sectional elevational view of the optical engine 700. The optical engine 700 includes several components that may be similar or identical to the components of the optical engine 100 of FIGS. 1A and 1B. Thus, some or all of the discussion above may be applicable to the optical engine 700.

The optical engine 700 includes a base substrate 702 having a top surface 704 and a bottom surface 706 opposite the top surface. The base substrate 702 may be formed from a material that is radio frequency (RF) compatible and is suitable for hermetic sealing. For example, the base substrate 702 may be formed from low temperature co-fired ceramic (LTCC), aluminum nitride (AlN), alumina, Kovar®, etc.

The optical engine 700 also includes a plurality of chip submounts 708 (only one chip submount visible in the sectional view of FIG. 7) that are bonded (e.g., attached) to the top surface 704 of the base substrate 702. The plurality of chip submounts 708 are aligned in a row across a width of the optical engine 700 between the left and right sides thereof. Each of the plurality of chip submounts 708 includes a laser diode 710, also referred to as a laser chip or laser die, bonded thereto. In particular, an infrared chip submount carries an infrared laser diode, a red chip submount carries a red laser diode, a green chip submount carries a green laser diode, and a blue chip submount carries a blue laser diode. In operation, the infrared laser diode provides infrared laser light, the red laser diode provides red laser light, the green laser diode provides green laser light, and the blue laser diode provides blue laser light. Each of the laser diodes 710 may comprise one of an edge emitter laser or a vertical-cavity surface-emitting laser (VCSEL), for example. Each of the four laser diode/chip submount pairs may be referred to collectively as a “laser chip on submount,” or a laser CoS 712. Thus, the optical engine 700 includes an infrared laser CoS, a red laser CoS, a green laser CoS, and a blue laser CoS. In at least some implementations, one or more of the laser diodes 710 may be bonded directly to the base substrate 702 without use of a submount 708.

The optical engine 700 also includes a laser diode driver circuit 714 bonded to the bottom surface 706 of the base substrate 702. The laser diode driver circuit 714 is operatively coupled to the plurality of laser diodes 710 via suitable electrical connections 716 to selectively drive current to the plurality of laser diodes. Generally, the laser diode driver circuit 714 may be positioned relative to the CoSs 712 to minimize the distance between the laser diode driver circuit 714 and the CoSs 712. Although not shown in FIG. 7, the laser diode driver circuit 714 may be operatively coupleable to a controller (e.g., microcontroller, microprocessor, ASIC) that controls the operation of the laser diode driver circuit 714 to selectively modulate laser light emitted by the laser diodes 710. In at least some implementations, the laser diode driver circuit 714 may be bonded to another portion of the base substrate 702, such as the top surface 704 of the base substrate, similar to the implementations shown in FIGS. 11A-11E. In at least some implementations, the laser diode driver circuitry 714 may be remotely located and operatively coupled to the laser diodes 710. In order to not require the use of impedance matched transmission lines, the size scale may be small compared to a wavelength (e.g., lumped element regime), where the electrical characteristics are described by (lumped) elements like resistance, inductance, and capacitance.

The optical engine 700 also includes a cap 720 that includes a vertical sidewall 722 and a horizontal wall or top portion 725. The vertical sidewall 722 includes a lower first end 724 and an upper second end 726 opposite the first end. A flange 728 may be disposed around a perimeter of the sidewall 722 adjacent the lower first end 724. Within a portion of the vertical sidewall 722 there is an optical window 730 positioned proximate the laser diodes 710 to pass light therefrom out of the cap 720. In some implementations, optical window 730 can extend from base substrate 702 to top portion 725, such that one side of cap 720 is formed entirely by optical window 730. The sidewall 722 and the optical window 730 together define an interior volume 732 sized and dimensioned to receive the plurality of chip submounts 708 and the plurality of laser diodes 710. The lower first end 724 and the flange 728 of the cap 720 are bonded to the base substrate 702 to provide a hermetic seal or a partial hermetic seal between the interior volume 732 of the cap and a volume 734 exterior to the cap.

The cap 720 may have a round shape, rectangular shape, or other shape. Thus, the vertical sidewall 722 may comprise a continuously curved sidewall, a plurality (e.g., four) of adjacent planar portions, etc. The optical window 730 may comprise an entire side of the cap 720, or may comprise only a portion thereof. In at least some implementations, the cap 720 may include a plurality of optical windows instead of a single optical window 730.

The optical engine 700 also includes four coupling lenses 736 (only one visible in the sectional view of FIG. 7), one for each of the four laser diodes 710 that are bonded to the top surface 704 of the base substrate 702 in a row. Each of the plurality of coupling lenses 736 is positioned and oriented to receive light from a corresponding one of the laser diodes 710 through the optical window 730.

The coupling lenses 736 couple the beams of light 610a-d (see FIG. 6) into the photonic integrated circuit 600 via the input optical edge 606. The photonic integrated circuit 600 may be bonded to the top surface 704 of the base substrate 702 proximate the row of coupling lenses 736. As discussed above, in operation, the photonic integrated circuit 600 receives a plurality of beams of light 610a-d at the input optical edge 606, and wavelength multiplexes the plurality of beams to provide a coaxially superimposed aggregate beam of light 612 that exits the photonic integrated circuit at the output optical edge 608.

In at least some implementations, the laser diodes 710 may be “butt” coupled to the photonic integrated circuit 600. In such implementations, the laser diodes 710 may be positioned immediately adjacent to a waveguide structure (e.g., photonic integrated circuit or other waveguide structure) such that sufficient coupling (e.g., acceptable insertion loss) is achieved without the use of a coupling lens.

Following out-coupling of the aggregate beam 612 from the output optical edge 608 of the photonic integrated circuit 600, the aggregated beam may be collimated via the common collimation lens 602, which may be bonded to the top surface 704 proximate the photonic integrated circuit 600. In at least some implementations, the collimation lens 602 may be either an achromatic lens or an apochromatic lens, depending on the particular optical design and tolerances of the system. In at least some implementations, the optical engine 700 may include one or more diffractive optical elements 604 bonded to the top surface 704 of the base substrate 702 to provide wavelength dependent focus correction.

In at least some implementations, at least some of the components may be positioned differently. As noted above, the laser diode driver circuit 714 may be mounted on the top surface 704 or the bottom surface 706 of the base substrate 702, or may be positioned remotely therefrom, depending on the RF design and other constraints (e.g., package size). In at least some implementations, the optical engine 700 may include optical director element (e.g., optical director element 118 of FIG. 1), and the laser light may be directed from the laser diodes 710 toward the coupling lenses 736 via an intermediate optical director element. Additionally, in at least some implementations, one or more of the laser diodes 710 may be mounted directly on the base substrate 702 without use of a submount. Further, in at least some implementations, in the case of an inorganic or acceptably organic waveguide (e.g., photonic integrated circuit), coupling may be accomplished inside the encapsulated package. Such feature eliminates the requirement for a separate window, as the waveguide services as the window (e.g., optical window 730). In such implementations, the at least one optical input edge of the photonic integrated circuit may be positioned inside the interior volume of the encapsulated package and the at least one optical output edge of the photonic integrated circuit may be positioned outside of the interior volume, for example.

For the sake of a controlled atmosphere inside the interior volume 732, it may be desirable to have no organic compounds inside the interior volume 732. In at least some implementations, the components of the optical engine 700 may be bonded together using no adhesives. In other implementations, a low amount of adhesives may be used to bond at least one of the components, which may reduce cost while providing a relatively low risk of organic contamination for a determined lifetime (e.g., 2 or more years) of the optical engine 700. Similarly to as detailed above regarding FIGS. 1A and 1B, partial hermeticity, a particulate dust cover, or even no protective cover may be acceptable for certain applications. Various bonding processes (e.g., attaching processes) for the optical engine 700 are discussed above with reference to FIG. 5.

Due to the divergent beam from each of the laser diodes 710 and the lateral distances between the laser diodes, the coupling lenses 736, and the photonic integrated circuit 600, it may be advantageous to minimize a distance between the respective output facets of the laser diodes 710 and the optical window 730. For the same reason, it may be advantageous to minimize the thickness of the optical window 730 and the size of the flange 728 of the cap 720 so that the coupling lenses 736 can be positioned relatively close to the output facets of the laser diodes 710. In at least some implementations, output window 730 and coupling lenses 736 could be formed as a single element.

In at least some implementations, the coupling lenses 736 and the collimation lens 602 may be actively aligned. In at least some implementations, the CoSs 712, the cap 720 (including optical window 730), and/or the photonic integrated circuit 600 may be passively aligned. Further, depending on the particular design, it may be advantageous to utilize a smaller base substrate 702 and use an additional carrier substrate instead.

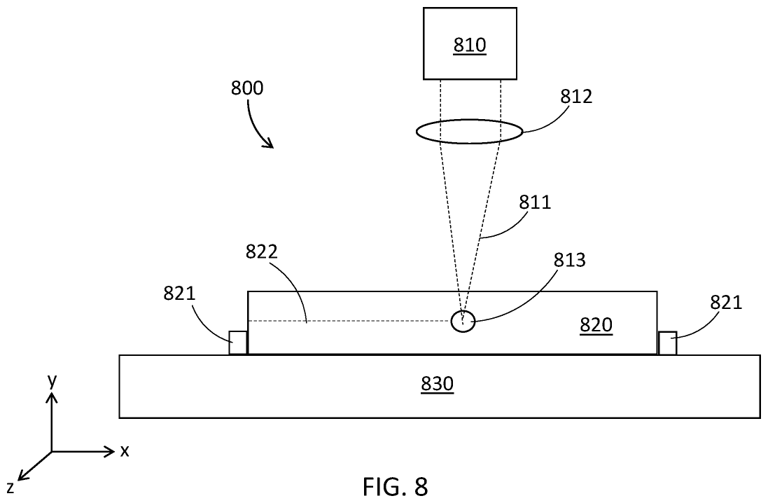

FIG. 8 is a schematic diagram of a laser writing system 800 in accordance with the present systems, designs and methods. Laser writing system 800 comprises at least writing laser 810, focusing optic 812, writeable glass 820 and translatable mount 830. Although the term “glass” is used herein for convenience, any appropriate laser-writable material could be used in place of writeable glass 820. Writing laser 810 emits laser light 811. Laser light 811 comprises short (femtosecond and/or picosecond length) pulses of laser light; consequently, laser light 811 has extremely high peak instantaneous power. Focusing optic 812 focuses laser light 811 to focal point 813. Writeable glass 820 may comprise a contiguous piece of glass or similar transparent material, which is typically transparent to the laser light 811 emitted by the writing laser 810; in other words the light emitted by the writing laser generally will not be absorbed by the glass via typical (linear) optical processes. At the focal point 813, the intensity of laser light 811 is very high due to the combination of spatial focusing (focusing the beam of writing laser light 811 to a small point 813) and temporal focusing (emitting the laser light 811 as extremely short femptosecond or picosecond pulses). The high intensity of light at the focal point 813 allows nonlinear optical processes such as multiphoton absorption, avalanche ionization, Coulomb collisions (causing lattice ionization and breakdown), and heat conduction to occur in the writeable glass 820, absorbing the light and changing the refractive index of the glass. The change in refractive index may be a positive increase in refractive index.

Writeable glass 820 can be physically coupled to translatable mount 830, such as by using clamps 821, adhesive, or any other appropriate coupling mechanism. Such coupling mechanism is preferably removable, such that writeable glass 820 can be detached from translatable mount 830 after laser writing is complete. Translation of translatable mount 830 in the X, Y, and/or Z direction will result in corresponding translation of writeable glass 820, moving the location of focal point 813 within writeable glass 820. Translating the writeable glass 820 relative to focal point 813 can create a region of changed refractive index in the writeable glass 820. An increased refractive index in this region causes any light channeled therethrough to experience total internal reflection, thus forming waveguide 822. In other words, waveguide 822 can be formed as a continuous path of increased refractive index within writeable glass 820 created by laser light 811 at focal point 813.

The technique of FIG. 8 can be used to laser write at least one waveguide into writeable glass 820. For example, a photonic integrated circuit could be written, such as photonic integrated circuit 600 described with regards to FIG. 6.

Writing at least one waveguide may include writing an individual waveguide for each wavelength of light impinging on the writeable glass 820, where each waveguide comprises a respective input facet and a respective output facet. Each output facet may be positioned to provide light to other components or modules, such as a scan mirror of a laser projector, etc. In one implementation, four waveguides could be written into writeable glass 820, one waveguide for each beam of light 610a, 610b, 610c, and 610d.

Writing at least one waveguide may include writing a waveguide combiner, wherein the waveguide combiner combines individual laser beams into a coaxially superimposed aggregate beam. Writing a waveguide combiner may include writing at least one: directional coupler (DC), Y-branch, whispering gallery mode coupler, or multi-mode interference coupler. The aggregate beam may be provided to other components or modules, such as a scan mirror of a laser projector, etc.

In other implementations, the photonic integrated circuit 600 may include one or more diffractive optical elements (DOE) and/or refractive/reflective optical elements that combine the different color beams 610a-d in order to achieve coaxial superposition.

Alternatively, instead of writing a waveguide combiner, individual waveguides could be writed or written which do not strictly coaxially superimpose the beams of light, but instead bring each beam of light close together. That is, the input facet for each waveguide in the photonic integrated circuit can be positioned relatively far from the other input facets, to receive laser light from a respective laser diode, but the output facets for each of the waveguides can be positioned relatively close together. In other words, a spacing between the output facets of each waveguide can be smaller than a spacing of the input facets of each waveguide. In such an implementation, each waveguide can be optimized for performance with light of a corresponding wavelength, for example to ensure that each wavelength of light exits the photonic integrated circuit with the same divergence angle as each other wavelength. The output of each individual waveguide can be placed close enough together (on the order of 10s of microns) such that that the light output by each individual waveguide may still follow the same optical path through the rest of a projector, display, or WHUD assembly where the photonic integrated circuit is implemented.

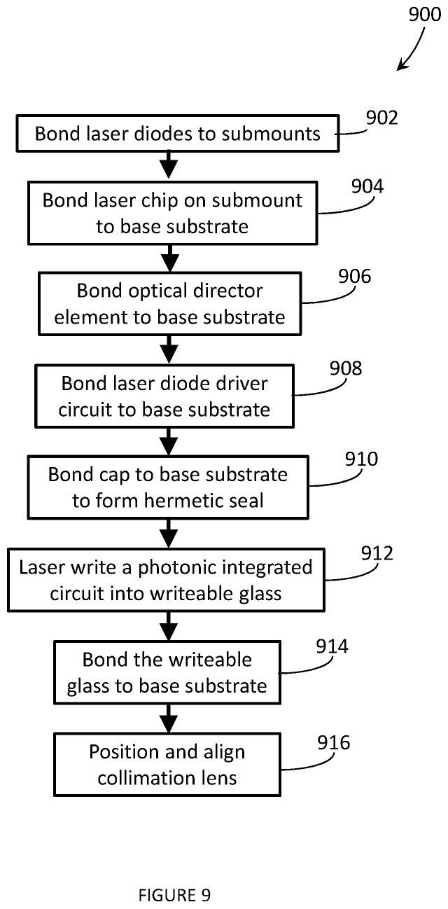

FIG. 9 is a flow diagram of a method 900 of manufacturing an optical engine, in accordance with the present systems, devices, and methods. The method 900 may be implemented to manufacture the optical engine 700 of FIG. 7, for example. It should be appreciated that methods of manufacturing optical engines according to the present disclosure may include fewer or additional acts than set forth in the method 900. Further, the acts discussed below may be performed in an order different than the order presented herein.

Method 900 can include at least acts 902, 904, 906, 908, 910, 912, 914, and 916. Acts 902, 904, 906, 908, and 910 substantially correspond to acts 502, 504, 506, 508, and 510, respectively, of method 500 in FIG. 5, such that the disclosure of these acts with reference to FIG. 5 is also applicable to FIG. 9. As such, the details of these acts in FIG. 9 will not be repeated in the interests of brevity.

At 912, a photonic integrated circuit is laser written in writeable glass, using for example the techniques described with regards to FIG. 8. The photonic integrated circuit may be similar to photonic integrated circuit 600 described with reference to FIG. 6. Specifically, the photonic integrated circuit can include at least one input optical edge and at least one output optical edge. In operation, the photonic integrated circuit can receive a plurality of beams of light that are edge coupled to the photonic integrated circuit at a plurality of input facets at the input optical edge, and wavelength multiplex the plurality of beams of light to provide a coaxially superimposed aggregate beam of light that exits the photonic integrated circuit at the output optical edge. Alternatively, in operation, the photonic integrated circuit can receive a plurality of beams of light that are edge coupled to the photonic integrated circuit at the input optical edge, redirect the plurality of beams of light to exit the photonic integrated circuit at the output optical edge close together.

At 914, the writeable glass including the photonic integrated circuit is bonded to the base substrate. Any appropriate bonding technique may be used, including those described with reference to acts 502, 504, 506, 508, and 510 in FIG. 5. In some implementations, the photonic integrated circuit may be butted against an optical window of the cap, such that laser light from the laser diodes may pass through the optical window directly into the input edge of the photonic integrated circuit. Alternatively, the photonic integrated circuit may be butted directly against the cap and/or laser diodes, such that the photonic integrated circuit acts as the optical window, and laser light from the laser diodes may directly enter the input edge of the photonic integrated circuit. In certain implementations, the input edge of the photonic integrated circuit may be positioned inside an interior volume of the cap, and the output edge of the photonic integrated circuit may be positioned outside the interior volume of the cap.

In order for light to travel through a photonic integrated circuit, the light emitted by each laser diode should preferably be aligned with a respective input facet on the input edge of the photonic integrated circuit with high precision; mis-alignment of greater than 10 micrometers may significantly reduce the efficiency of the photonic integrated circuit. An output facet of each laser diode may have dimensions smaller than four square micrometers; aligning such small components to such high precision presents a non-trivial technical challenge.

In one implementation, instead of butting the input edge of the photonic integrated circuit against the optical window of the cap, the photonic integrated circuit can be bonded to the base substrate a distance away from the optical window, and coupling lenses such as coupling lenses 736 in FIG. 7 may be bonded to the base substrate between the optical window and the photonic integrated circuit. The coupling lenses can be aligned to couple light from each laser diode into a respective input facet at the input edge of the photonic integrated circuit.

In act 916, a collimation lens may be provided such that a coaxially superimposed beam of light from the output edge of the photonic integrated circuit will be collimated by the collimation lens. The collimation lens may optionally optimize the spot (e.g., circularize) the coaxially superimposed beam. In some implementations, more than one collimation lens may be provided if the light output from the photonic integrated circuit is not a fully coaxially superimposed beam. The collimation lens or lenses may be actively aligned after the other components are assembled, or may be passively aligned such that appropriate alignment is achieved during assembly.

As mentioned above, aligning a photonic integrated circuit such that each input facet on an input edge of the photonic integrated circuit lines up with a beam of light emitted by each laser diode with high-precision presents a non-trivial challenge. The present systems, devices, and methods provide a solution to this challenge, by producing photonic integrated circuits where the fabrication process includes an alignment process, obviating the need for a later mechanical alignment process, as discussed below with reference to FIG. 10. Direct laser writing (DLW) as disclosed herein is a process by which photonic integrated circuits may be fabricated with high precision that allows for intrinsic alignment.

FIG. 10 is a left side sectional view of photonic integrated circuit writing system 1000. Photonic integrated circuit writing system 1000 includes components that may be substantively similar to components of optical engine 700 and components of laser writing system 800. Unless context below dictates otherwise, the disclosure of components in FIG. 7 and FIG. 8 is applicable to similarly numbered components in FIG. 10 and will not be repeated in the interests of brevity. Photonic integrated circuit writing system 1000 includes laser writing system 800, which, during operation, writes a photonic integrated circuit in a block of writeable glass 820 in a manner similar to the operation of laser writing system 800 described above with reference to FIG. 8. Photonic integrated circuit writing system 1000 can be utilized to manufacture an optical engine using a process that is similar in at least some respects to method 900 of FIG. 9, but with photonic integrated circuit writing system 1000, act 914 can be performed before act 912, as detailed below.

Writeable glass 820 is bonded to base substrate 702 prior to writing a photonic integrated circuit therein, using any of the bonding techniques discussed above. The writeable glass 820 may comprise a contiguous piece of glass or similar transparent material that undergoes a change in refractive index when exposed to high-intensity laser light. Bonding the writeable glass to the base substrate includes positioning and orienting the writeable glass 820 relative to each laser diode 710 to place the writeable glass 820 in the path of the beam of light emitted by each laser diode 710, such that the beam of light emitted by each laser diode 710 impinges on an input edge of the writeable glass.

Writeable glass 820 can be butted up against optical window 730, such that beams of light from laser diodes 710 passes through optical window 730 directly into writeable glass 820. Alternatively, the writeable glass 820 may optionally form optical window 730. Further, writeable glass 820 may be bonded directly to at least one of the laser diodes 710 and/or at least one laser CoS 712.

The entire base substrate 702 and all components bonded thereto can be physically coupled to translatable mount 830, such as with clamps 821, adhesives, and/or any other appropriate coupling mechanism. Such coupling mechanism is preferably removable, such that base substrate 702 and all components bonded thereto can be detached from translatable mount 830 after laser writing of writeable glass 820 is complete.

With writeable glass 820 bonded to base substrate 702 and base substrate 702 physically coupled to translatable mount 830, at least one waveguide 822 can be laser written into writeable glass 820 by translating base substrate 702 and all components thereon using translatable mount 830. Consequently, writeable glass 820 becomes a photonic integrated circuit.

To determine where the at least one waveguide 822 should be written, laser diodes 710 could be activated, thus causing beams of light therefrom to impinge on an input edge of writeable block 820. Writing laser 810 can be aligned to directly write waveguides at the exact location where the beams of light from laser diodes 710 impinge on the writeable block 820. In this way, the input of the resulting photonic integrated circuit will be accurately aligned with the laser diodes, ensuring efficient incoupling of the beams of light into the photonic integrated circuit.

Alternatively, the writeable glass 820 could be illuminated, such as by being backlit if base substrate 702 is at least partially transparent. Writing laser 810 can then be aligned to directly write waveguides at locations where shadows of laser diodes 710 and/or CoS's 712 appear. In this way, the input of the resulting photonic integrated circuit will be accurately aligned with the laser diodes, ensuring efficient incoupling of the beams of light into the photonic integrated circuit.

Aligning the input facets of the photonic integrated circuit to the beams of light during the writing stage will be more accurate than trying to mechanically align a pre-fabricated photonic integrated circuit, due to deviations that can arise in the bonding processes of not only the pre-fabricated photonic integrate circuit, but also the laser diodes. As one example, if each of four laser diodes is randomly misaligned, it would be difficult to align a prefabricated photonic integrated circuit to match the beam of light from each diode, since not only could the photonic integrated circuit be misaligned during the bonding processes, but also the spacing between each laser diode may not match the spacing between each waveguide in the photonic integrated circuit due to the random misalignment of each of the laser diodes. Direct laser writing the photonic integrated circuit after all of the components have been mechanically bonded obviates these issues, by allowing the position and spacing of each laser diode relative to the writeable glass to be accounted for after bonding is complete.

In some implementations, a photonic integrated circuit could be manufactured using a combination of the techniques described with reference to FIGS. 8, 9, and 10, as discussed below.

In one example, a large portion of a photonic integrated circuit could be first written, except for a small portion of the photonic integrated circuit at the input edge of writeable glass. Subsequently, the photonic integrated circuit could be bonded to a base substrate such as in FIG. 10, and the remaining small portion of the photonic integrated circuit at the input edge of the writeable glass could be written to couple the output of each laser diode to the portion of the photonic integrated circuit which is already written.

In another example, a first photonic integrated circuit could be written as in FIG. 8. Subsequently, the first photonic integrated circuit could be bonded to a base substrate similar to in FIG. 7, with a gap between the optical window and the input edge of the first photonic integrated circuit. In the gap between the optical window and the photonic integrated circuit, instead of positioning coupling lenses, a block of writeable glass could be bonded to the base substrate. Subsequently, a second photonic integrated circuit could be written in the writeable glass similar to in FIG. 10 to couple the output of each laser diode to the input edge of the previously written photonic integrated circuit. In this example, the block of writeable glass could be formed as the optical window, and/or could be formed to cover a portion of the first photonic integrate circuit.

In some implementations, an optical engine similar to optical engine 700 may include a beam combiner 316 as described with regards to FIG. 3 in place of photonic integrated circuit 600. FIG. 11A illustrates an exemplary optical engine 1100 in this regard.

FIG. 11A is a top side sectional elevational view of optical engine 1100a. The optical engine 1100 includes several components that may be similar or identical to the components of the optical engine 100 of FIGS. 1A and 1B and/or the optical engine 700 of FIG. 7. Thus, some or all of the discussion above may be applicable to the optical engine 1100a.

The optical engine 1100a includes a base substrate 1102. The base substrate 1102 may be formed from a material that is radio frequency (RF) compatible and is suitable for hermetic sealing. For example, the base substrate 1102 may be formed from low temperature co-fired ceramic (LTCC), aluminum nitride (AlN), alumina, Kovar®, etc.

The optical engine 1100a also includes a plurality of chip submounts 1108a, 1108b, 1108c, and 1108d that are bonded (e.g., attached) to the base substrate 1102. The plurality of chip submounts 1108a, 1108b, 1108c, and 1108d are aligned in a row across a width of the optical engine 1100 between the left and right sides thereof. Each of the plurality of chip submounts 1108a, 1108b, 1108c, and 1108d includes a respective laser diode 1110a, 1110b, 1110c, 1110d, also referred to as a laser chip or laser die, bonded thereto. In particular, an infrared chip submount 1108d carries an infrared laser diode 1110d, a red chip submount 1108a carries a red laser diode 1110a, a green chip submount 1108b carries a green laser diode 1110b, and a blue chip submount 1108c carries a blue laser diode 1110c. In operation, the infrared laser diode 1110d provides infrared laser light 1138d, the red laser diode 1110a provides red laser light 1138a, the green laser diode 1110b provides green laser light 1138b, and the blue laser diode 1110c provides blue laser light 1138c. Each of the laser diodes 1110a, 1110b, 1110c, and 1110d may comprise one of an edge emitter laser or a vertical-cavity surface-emitting laser (VCSEL), for example. Each of the four laser diode/chip submount pairs may be referred to collectively as a “laser chip on submount,” or a laser CoS. Thus, the optical engine 1100a includes an infrared laser CoS 1112d, a red laser CoS 1112a, a green laser CoS 1112b, and a blue laser CoS 1112c. In at least some implementations, one or more of the laser diodes 1110a, 1110b, 1110c, and 1110d may be bonded directly to the base substrate 1102 without use of a submount, as described above with reference to act 504 in FIG. 5.

The optical engine 1100a also includes a laser diode driver circuit 1114 bonded to the base substrate 1102. In FIG. 11A, laser diode driver circuit 1114 is illustrated as being bonded to a top surface of base substrate 1102, but in at least some implementations, the laser diode driver circuit 1114 may be bonded to another portion of the base substrate 1102, such as a bottom surface of the base substrate 1102. The laser diode driver circuit 1114 is operatively coupled to the plurality of laser diodes 1110a, 1110b, 1110c, and 1110d via respective electrical connections 1116a, 1116b, 1116c, and 1116d to selectively drive current to the plurality of laser diodes. Generally, the laser diode driver circuit 1114 may be positioned relative to the CoSs 1112a, 1112b, 1112c, and 1112d to minimize the distance between the laser diode driver circuit 1114 and the CoSs 1112a, 1112b, 1112c, and 1112d. Although not shown in FIG. 11A, the laser diode driver circuit 1114 may be operatively coupleable to a controller (e.g., microcontroller, microprocessor, ASIC) that controls the operation of the laser diode driver circuit 1114 to selectively modulate laser light emitted by the laser diodes 1110a, 1110b, 1110c, and 1110d. In at least some implementations, the laser diode driver circuitry 1114 may be remotely located and operatively coupled to the laser diodes 1110a, 1110b, 1110c, and 1110d. In order to not require the use of impedance matched transmission lines, the size scale may be small compared to a wavelength (e.g., lumped element regime), where the electrical characteristics are described by (lumped) elements like resistance, inductance, and capacitance.

The optical engine 1100a also includes a cap 1120, which can be similar to cap 720 as discussed regarding FIG. 7. Within a portion of the cap 1120 there is an optical window 1130 positioned proximate the laser diodes 1110a, 1110b, 1110c, and 1110d to pass light therefrom out of the cap 1120. The cap 1120 and optical window 1130 define an interior volume 1132 sized and dimensioned to receive the plurality of chip submounts 1108a, 1108b, 1108c, 1108d and the plurality of laser diodes 1110a, 1110b, 1110c, and 1110d. Cap 1120 is bonded to the base substrate 1102 to provide a hermetic seal or a partial hermetic seal between the interior volume 1132 of the cap and a volume exterior to the cap.

The cap 1120 may have a round shape, rectangular shape, or other shape. The optical window 1130 may comprise an entire side of the cap 1120, or may comprise only a portion thereof. In at least some implementations, the cap 1120 may include a plurality of optical windows instead of a single optical window 1130.

The optical engine 1100 also includes four collimation/pointing lenses 1136a, 1136b, 1136c, and 1136d, one for each respective laser diode 1110a, 1110b, 1110c, and 1110d that are bonded to the base substrate 1102 in a row. Each of the plurality of collimation lenses 1136a, 1136b, 1136c, and 1136d is positioned and oriented to receive light from a corresponding one of the laser diodes 1110a, 1110b, 1110c, and 1110d through the optical window 1130.

The collimation lenses 1136a, 1136b, 1136c, and 1136d couple the respective beams of light 1138a, 1138b, 1138c, and 1138d into respective optical elements 328, 330, 332, and 334 of a beam combiner 316. Beam combiner 316 in FIG. 11A could be similar to beam combiner 316 illustrated in FIG. 3, such that the description regarding FIG. 3 can be applicable to the beam combiner 316 in FIG. 11A. The beam combiner 316 may be bonded to the base substrate 1102 proximate the row of collimation lenses 1136a, 1136b, 1136c, and 1136d. As discussed above regarding FIG. 3, in operation, beam combiner 316 receives a plurality of beams of light 1138a, 1138b, 1138c, and 1138d and combines the plurality of beams to provide a coaxially superimposed aggregate beam of light 336.

In at least some implementations, at least some of the components may be positioned differently. As noted above, the laser diode driver circuit 1114 may be mounted on a top surface or a bottom surface of the base substrate 1102, or may be positioned remotely therefrom, depending on the RF design and other constraints (e.g., package size). In at least some implementations, the optical engine 1100a may include an optical director element (e.g., optical director element 118 of FIG. 1), and the laser light may be directed from the laser diodes 1110a, 1110b, 1110c, and 1110d toward the collimation lenses 1136a, 1136b, 1136c, 1136d via an intermediate optical director element. Additionally, in at least some implementations, one or more of the laser diodes 1110a, 1110b, 1110c, and 1110d may be mounted directly on the base substrate 1102 without use of a submount.

For the sake of a controlled atmosphere inside the interior volume 1132, it may be desirable to have no organic compounds inside the interior volume 1132. In at least some implementations, the components of the optical engine 1100 may be bonded together using no adhesives. In other implementations, a low amount of adhesives may be used to bond at least one of the components, which may reduce cost while providing a relatively low risk of organic contamination for a determined lifetime (e.g., 2 or more years) of the optical engine 1100. Similarly to as detailed above regarding FIGS. 1A and 1B, partial hermeticity, a particulate dust cover, or even no protective cover may be acceptable for certain applications. Various bonding processes (e.g., attaching processes) for the optical engine 1100a are discussed above with reference to FIG. 5.

Due to the divergent beam from each of the laser diodes 1110a, 1110b, 1110c, and 1110d and the lateral distances between the laser diodes, the collimation lenses 1136a, 1136b, 1136c, and 1136d, and the beam combiner 316, it may be advantageous to minimize a distance between the respective output facets of the laser diodes 1110a, 1110b, 1110c, and 1110d and the optical window 1130. For the same reason, it may be advantageous to minimize the thickness of the optical window 1130 so that the collimation lenses 1136a, 1136b, 1136c, and 1136d can be positioned relatively close to the output facets of the laser diodes 1110a, 1110b, 1110c, and 1110d.

In at least some implementations, the collimation lenses 1136a, 1136b, 1136c, and 1136d may be actively aligned. In at least some implementations, the CoSs 1112a, 1112b, 1112c, and 1112d, the cap 1120 (including optical window 1130), and/or the beam combiner 316 may be passively aligned.

Depending on the particular design, it may be advantageous to utilize a smaller base substrate 1102 and use at least one additional carrier substrate to carry one or both of the collimation lenses 1136a, 1136b, 1136c, and 1136d; and/or the beam combiner 316 instead.

FIG. 11A also illustrates an insulating cover 1140 over electrical connections 1116a, 1116b, 1116c, and 1116d. Since cap 1120 can be formed of a conductive material, insulating cover 1140 prevents electrical signals which run through electrical connections 1116a, 1116b, 1116c, and 1116d from transmitting into or through cap 1120. FIG. 11B is an isometric view showing insulating cover 1140 in more detail. In FIG. 11B, CoSs 1112a, 1112b, 1112c, and 1112d are each connected to laser diode driver circuitry 1114 by a respective electrical connection 1116a, 1116b, 1116c, or 1116d. Electrical connections 1116a, 1116b, 1116c, and 1116d run across a surface of the base substrate 1102. Insulating cover 1140 is placed, adhered, formed, or otherwise positioned over electrical connections 1116a, 1116b, 1116c, and 1116d, such that each of the electrical connections 1116a, 1116b, 1116c, and 1116d run through insulating cover 1140. Cap 1120 is placed, adhered, formed, or otherwise positioned over insulating cover 1140, such that cap 1120 does not contact any of the electrical connections 1116a, 1116b, 1116c, or 1116d. For clarity, cap 1120 is shown as being transparent in FIG. 11B, though this is not necessarily the case, and cap 1120 can be formed of an opaque material. Insulating cover 1140 can be formed of a material with low electrical permittivity such as a ceramic, such that electrical signals which run through electrical connections 1116a, 1116b, 1116c, and 1116d do not run into or through insulating cover 1140. In this way, electrical signals which run through electrical connections 1116a, 1116b, 1116c, and 1116d can be prevented from running into or through cap 1120, which can be formed of an electrically conductive material. Although FIG. 11B shows insulating cover 1140 as extending along only part of a side of cap 1120, one skilled in the art will appreciate that insulating cover 1140 can extend along an entire side length of cap 1120.

One skilled in the art will appreciate that the positions of laser diode driver circuitry 1114, electrical connections 1116a, 1116b, 1116c, 1116d, and insulating cover 1140 as shown in FIGS. 11A and 11B could also be applied in other implementations of the subject systems, devices and methods. For example, in the implementation of FIGS. 1A and 1B, laser diode driver circuitry 114 could be positioned on top surface 104 of base substrate 102, and electrical connections 116 could run across top surface 104 under an insulating cover, such that electrical connections 116 do not contact any conductive portion of cap 120. Similarly, in the implementations of FIGS. 7 and 10, laser diode driver circuitry 714 could be positioned on top surface 704 of base substrate 702, and electrical connections 716 could run across top surface 704 under an insulating cover, such that electrical connections 716 do not contact any conductive portion of cap 720.

FIGS. 11C, 11D, and 11E illustrate alternative implementations of the optical engine 1100a shown in FIGS. 11A and 11B. One skilled in the art will appreciate that, unless context clearly dictates otherwise, the description of FIGS. 11A and 11B is applicable to the implementations of FIGS. 11C, 11D, and 11E.

FIG. 11C is a top side sectional elevational view of an optical engine 1100c similar to optical engine 1100a of FIG. 11A. The optical engine 1100c includes a base substrate 1103. Similar to base substrate 1102 in FIG. 11A, base substrate 1103 may be formed from a material that is radio frequency (RF) compatible and is suitable for hermetic sealing. For example, the base substrate 1103 may be formed from low temperature co-fired ceramic (LTCC), alumina, Kovar®, etc.

One difference between optical engine 1100c in FIG. 11C and optical engine 1100a in FIG. 11A relates to what components are bonded (e.g. attached) to base substrate 1103. In optical engine 1100c, each of: CoSs 1112a, 1112b, 1112c, 1112d; cap 1120; optical window 1130; electrical connections 1116a, 1116b, 1116c, 1116d; and insulating cover 1140 are bonded (e.g., attached) to base substrate 1103. However, laser diode driver circuit 1114, collimation lenses 1136a, 1136b, 1136c, 1136d and beam combiner 316 are not necessarily bonded directly to base substrate 1103. Instead, any of these of these components could be bonded to a separate base substrate. For example, each of laser diode driver circuit 1114, collimation lenses 1136a, 1136b, 1136c, 1136d, and beam combiner 316 could be bonded to separate base substrates. As another example, collimation lenses 1136a, 1136b, 1136c, 1136d, and beam combiner 316 could be bonded a first separate base substrate, and laser diode drive circuit 1114 could be bonded to a second separate base substrate. As another example, collimation lenses 1136a, 1136b, 1136c, and 1136d could be bonded to a first separate substrate, laser diode drive circuit 1114 could be bonded to a second separate substrate, and beam combiner 316 could be bonded to a third separate substrate. Further, it is also within the scope of the subject systems, devices, and methods for at least some of laser diode drive circuit 1114, collimation lenses 1136a, 1136b, 1136c, 1136d, and beam combiner 316 to be bonded to base substrate 1103. As an example, laser diode drive circuit 1114 could be bonded to base substrate 1103, but collimation lenses 1136a, 1136b, 1136c, 1136d, and beam combiner 316 could be bonded to a separate base substrate. As another example, collimation lenses 1136a, 1136b, 1136c, 1136d, and beam combiner 316 could be bonded to base substrate 1103, but laser diode drive circuit 1114 could be bonded to a separate base substrate. As another example, collimation lenses 1136a, 1136b, 1136c, and 1136d could be bonded to base substrate 1103, but laser diode drive circuit 1114 could be bonded to a first separate base substrate, and beam combiner 314 could be bonded to a second separate base substrate. Further, beam combiner 316, collimation lenses 1136a, 1136b, 1136c, 1136d, and laser diode drive circuit 1114 may not need to be bonded to a substrate at all, and could simply be mounted directly within a frame of a WHUD.

For the cases where laser diode drive circuit 1114 is not bonded to base substrate 1103, electrical contacts 1117a, 1117b, 1117c, and 1117d could be bonded to base substrate 1103, each at an end of a respective electrical connection 1116a, 1116b, 1116c, or 1116d. In this way, electrical contacts 1117a, 1117b, 1117c, and 1117d could be used to electrically couple laser diode drive circuit 1114 to electrical connections 1116a, 1116b, 1116c, and 1116d.

FIG. 11D is a top side sectional elevational view of an optical engine 1100d similar to optical engine 1100a of FIG. 11A and optical engine 1100c of FIG. 11C. Optical engine 1100d includes a beam combiner 317 which is similar to beam combiner 316 as shown in FIGS. 11A and 11C, but bigger in size relative to the other components of FIG. 11D. Beam combiner 317 functions to produce an aggregate beam 337 in a similar manner to how beam combiner 316 produces aggregate beam 336 as disclosed regarding FIGS. 3A and 3B, such that the descriptions throughout this application pertaining to beam combiner 316 are applicable to beam combiner 317. Further, the descriptions pertaining to optical elements 328, 330, 332, and 334 of beam combiner 316 are applicable to optical elements 329, 331, 333, and 335 of beam combiner 317.

In optical engine 1100d of FIG. 11D, beam combiner 317 is large in size relative to the other components of the FIG. 11D, such that each light beam 1138a, 1138b, 1138c, and 1138d does not line up directly with a respective optical element 329, 331, 333, and 335. To address this issue, at least one of collimation lens 1136a, 1136b, 1136c, and 1136d can be aligned to redirect a respective light beam 1138a, 1138b, 1138c, or 1138d towards a respective optical element 329, 331, 333, or 335. As an example, at least one collimation lens 1136a, 1136b, 1136c, or 1136d could be rotated with respect to a respective beam of light 1138a, 1138b, 1138c, or 1138d. As another example, at least one collimation lens 1136a, 1136b, 1136c, and 1136d could be formed in a skewed shape which redirects a respective beam of light 1138a, 1138b, 1138c, or 1138d appropriately. As another example, at least one collimation lens 1136a, 1136b, 1136c, or 1136d could include a waveguide, or be formed as a waveguide, to redirect a respective beam of light 1138a, 1138b, 1138c, or 1138d.

FIG. 11E is a top side sectional elevational view of an optical engine 1100e similar to optical engine 1100a of FIG. 11A, optical engine 1100c of FIG. 11C, and optical engine 1100d of FIG. 11D. Optical engine 1100e includes a collimation lens 1137 positioned near an output side of beam combiner 316. In one implementation, collimation lens 1137 could replace collimation lenses 1136a, 1136b, 1136c, and 1136d, such that uncollimated beams of light 1138a, 1138b, 1138c, and 1138d enter beam combiner 316, and collimation lens 1137 collimates aggregate beam 336 output from beam combiner 316. In another implementation, collimation lens 1137 could be in addition to collimation lenses 1136a, 1136b, 1136c, and 1136d, such that roughly collimated or partially collimated beams of light 1138a, 1138b, 1138c, and 1138d enter beam combiner 316, and collimation lens 1137 fully collimates and/or corrects aggregate beam 336 output from beam combiner 316.

One skilled in the art will appreciate that even though FIGS. 11D and 11E show optical engines having base substrate 1103 with only a subset of components bonded thereto, the implementations of FIGS. 11D and 11E could utilize any of the base substrate implementations illustrated or discussed with regards to FIG. 11C, as well as the base substrate implementation illustrated and discussed with regards to FIG. 11A. Further, it is within the scope of the present systems, devices, and methods that any of the implementations discussed herein could utilize any appropriate base substrate implementations illustrated or discussed with regards to FIG. 11C.

Throughout this application, many collimation lenses are represented in the Figures by a simple curved lens shape. However, the subject systems, devices, and methods can utilize more advanced collimation schemes, as appropriate for a given application.

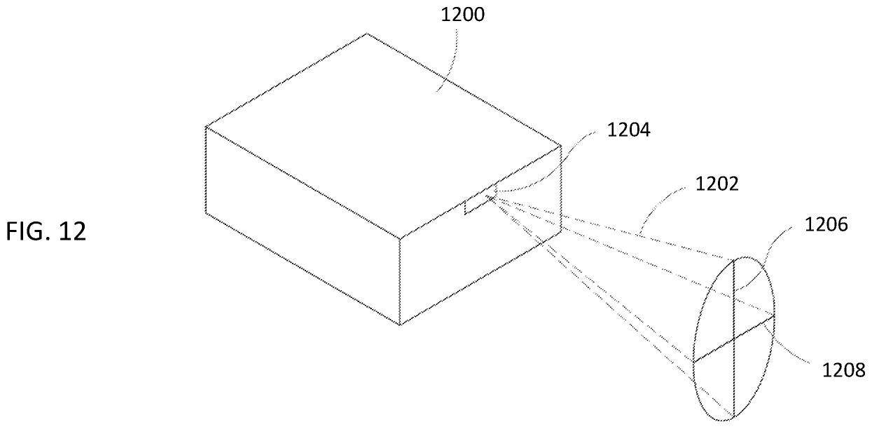

FIG. 12 shows an exemplary situation where using an advanced collimation scheme would be helpful. FIG. 12 is an isometric view of a laser diode 1200. The laser diode 1200 may be similar or identical to the various laser diodes discussed herein. The laser diode 1200 outputs a laser light beam 1202 via an output facet 1204 of the laser diode. FIG. 12 shows the divergence of the light 1202 emitting from the laser diode 1200. As shown, the light beam 1202 may diverge by a substantial amount along a fast axis 1206 (or perpendicular axis) and by a lesser amount in the slow axis 1208 (parallel axis). As a non-limiting example, in at least some implementations, the light beam 1202 may diverge with full width half maximum (FWHM) angles of up to 40 degrees in the fast axis direction 1206 and up to 10 degrees in the slow axis direction 1208. This divergence results in a rapidly expanding elliptical cone.

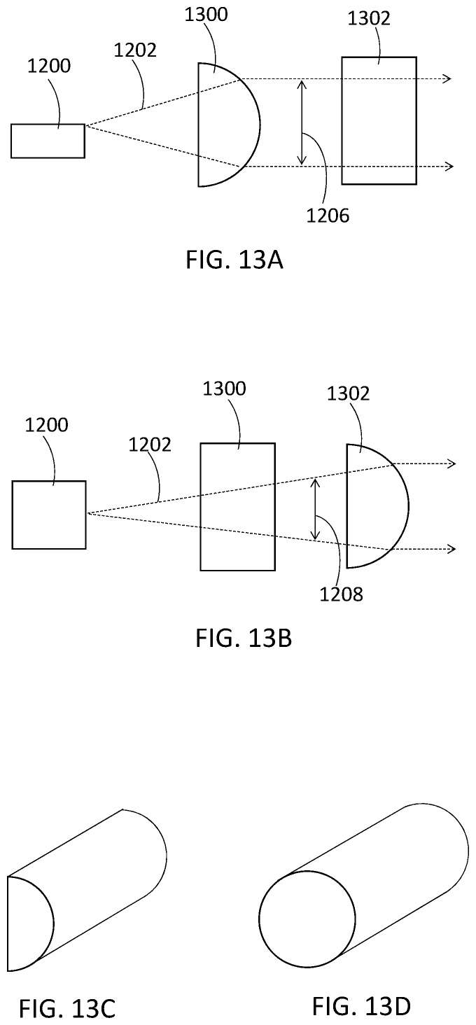

FIGS. 13A and 13B show an exemplary collimation scheme that can be used to circularize and collimate an elliptical beam such as that shown in FIG. 12. FIG. 13A illustrates an orthogonal view of the fast axis 1206 of light beam 1202 emitted from laser diode 1200. FIG. 13B illustrates an orthogonal view of the slow axis 1208 of light beam 1202 emitted from laser diode 1200. As shown in FIG. 13A, a first lens 1300 collimates light beam 1202 along fast axis 1206. As shown in FIG. 13B, first lens 1300 is shaped so as to not substantially influence light beam 1202 along slow axis 1208. Subsequently, as shown in FIG. 13B, light beam 1202 is collimated along slow axis 1208 by a second lens 1302. As shown in FIG. 13A, second lens 1302 is shaped so as to not substantially influence light beam 1202 along fast axis 1206. In essence, light beam 1202 is collimated along fast axis 1206 separately from slow axis 1208. By collimating light beam 1202 along fast axis 1206 separately from slow axis 1208, the collimation power applied to each axis can be independently controlled by controlling the power of lens 1300 and lens 1302 separately. Further, spacing between each of laser diode 1200, lens 1300, and lens 1302 can be controlled to collimate light beam 1202 to a certain width in each axis separately. If light beam 1202 is collimated along fast axis 1206 to the same width as slow axis 1208, light beam 1202 can be circularized. Because light beam 1202 will typically diverge faster in the fast axis 1206, it is generally preferable to collimate light beam 1202 along fast axis 1206 first, then collimate light beam 1202 along slow axis 1208 after. However, it is possible in certain applications to collimate light beam 1202 along slow axis 1208 first, and subsequently collimate light beam 1202 along fast axis 1206 after. This can be achieved by reversing the order of first lens 1300 with second lens 1302, with respect to the path of travel of light beam 1202.

FIGS. 13C and 13D are isometric views which illustrate exemplary shapes for lenses 1300 and 1302. Each of lens 1300 and 1302 can be for example a half-cylinder as in FIG. 13C, a full cylinder as in FIG. 13D, a quarter cylinder, a three-quarter cylinder, any other partial cylinder, or any other appropriate shape. Lens 1300 and 1302 can be similarly shaped, or can have different shapes.

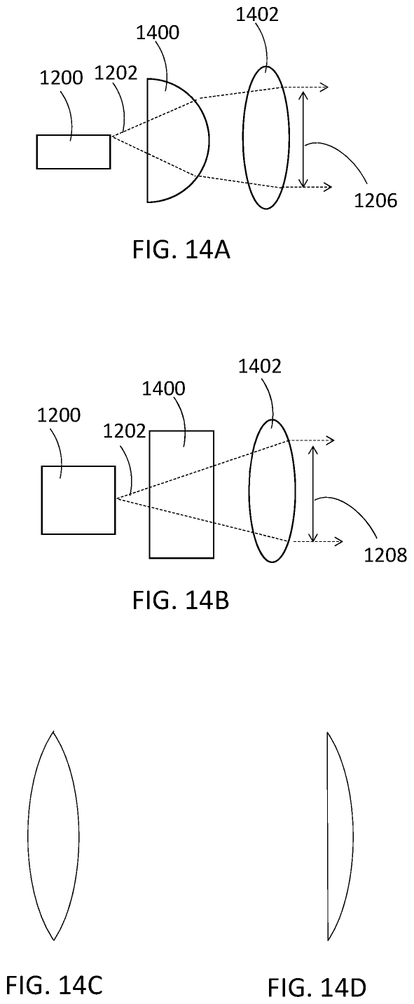

FIGS. 14A and 14B illustrate an alternative collimation scheme. FIG. 14A illustrates an orthogonal view of the fast axis 1206 of light beam 1202 emitted from laser diode 1200. FIG. 14B illustrates an orthogonal view of the slow axis 1208 of light beam 1202 emitted from laser diode 1200. As shown in FIG. 14A, a first lens 1400 redirects light beam 1202 along fast axis 1206, to reduce divergence of light beam 1202 along fast axis 1206. As shown in FIG. 14B, first lens 1400 is shaped so as to not substantially influence light beam 1202 along slow axis 1208. Preferably, first lens 1400 will reduce divergence of light beam 1202 along fast axis 1206 to match divergence of light beam 1202 along slow axis 1208. That is, first lens 1400 preferably circularizes light beam 1202. Subsequently, as shown in FIGS. 14A and 14B, light beam 1202 is collimated along both fast axis 1206 and slow axis 1208 by a second lens 1402. As shown in FIGS. 14A and 14B, second lens 1402 is shaped similarly with respect to both the fast axis 1206 and the slow axis 1208, to evenly collimate light beam 1202. In essence, first lens 1400 circularizes light beam 1202, and subsequently second lens 1402 collimates light beam 1202 along both axes. First lens 1400 can for example be shaped similarly to lens 1300 or lens 1302 discussed above, and shown in FIGS. 14C and 14D. Second lens 1402 can for example be shaped as a double convex lens as illustrated in FIG. 14C, or a single convex lens (convex on either side) as illustrated in FIG. 14D, or any other appropriate collimating lens.

The collimation schemes illustrated in FIGS. 13A-13D and 14A-14D, and discussed above could be used in place of any of the collimation lenses described herein, including at least collimation lenses 136a, 136b, 136c, 136d, collimation lens 602, and coupling lenses 736.

A person of skill in the art will appreciate that the teachings of the present systems, methods, and devices may be modified and/or applied in additional applications beyond the specific WHUD implementations described herein. In some implementations, one or more optical fiber(s) may be used to guide light signals along some of the paths illustrated herein.

The WHUDs described herein may include one or more sensor(s) (e.g., microphone, camera, thermometer, compass, altimeter, and/or others) for collecting data from the user's environment. For example, one or more camera(s) may be used to provide feedback to the processor of the WHUD and influence where on the display(s) any given image should be displayed.

The WHUDs described herein may include one or more on-board power sources (e.g., one or more battery(ies)), a wireless transceiver for sending/receiving wireless communications, and/or a tethered connector port for coupling to a computer and/or charging the one or more on-board power source(s).

The above description of illustrated embodiments, including what is described in the Abstract, is not intended to be exhaustive or to limit the embodiments to the precise forms disclosed. Although specific embodiments of and examples are described herein for illustrative purposes, various equivalent modifications can be made without departing from the spirit and scope of the disclosure, as will be recognized by those skilled in the relevant art. The teachings provided herein of the various embodiments can be applied to other portable and/or wearable electronic devices, not necessarily the exemplary wearable electronic devices generally described above.

For instance, the foregoing detailed description has set forth various embodiments of the devices and/or processes via the use of block diagrams, schematics, and examples. Insofar as such block diagrams, schematics, and examples contain one or more functions and/or operations, it will be understood by those skilled in the art that each function and/or operation within such block diagrams, flowcharts, or examples can be implemented, individually and/or collectively, by a wide range of hardware, software, firmware, or virtually any combination thereof. In one embodiment, the present subject matter may be implemented via Application Specific Integrated Circuits (ASICs). However, those skilled in the art will recognize that the embodiments disclosed herein, in whole or in part, can be equivalently implemented in standard integrated circuits, as one or more computer programs executed by one or more computers (e.g., as one or more programs running on one or more computer systems), as one or more programs executed by on one or more controllers (e.g., microcontrollers) as one or more programs executed by one or more processors (e.g., microprocessors, central processing units, graphical processing units), as firmware, or as virtually any combination thereof, and that designing the circuitry and/or writing the code for the software and or firmware would be well within the skill of one of ordinary skill in the art in light of the teachings of this disclosure.

When logic is implemented as software and stored in memory, logic or information can be stored on any processor-readable medium for use by or in connection with any processor-related system or method. In the context of this disclosure, a memory is a processor-readable medium that is an electronic, magnetic, optical, or other physical device or means that contains or stores a computer and/or processor program. Logic and/or the information can be embodied in any processor-readable medium for use by or in connection with an instruction execution system, apparatus, or device, such as a computer-based system, processor-containing system, or other system that can fetch the instructions from the instruction execution system, apparatus, or device and execute the instructions associated with logic and/or information.

In the context of this specification, a “non-transitory processor-readable medium” can be any element that can store the program associated with logic and/or information for use by or in connection with the instruction execution system, apparatus, and/or device. The processor-readable medium can be, for example, but is not limited to, an electronic, magnetic, optical, electromagnetic, infrared, or semiconductor system, apparatus or device. More specific examples (a non-exhaustive list) of the computer readable medium would include the following: a portable computer diskette (magnetic, compact flash card, secure digital, or the like), a random access memory (RAM), a read-only memory (ROM), an erasable programmable read-only memory (EPROM, EEPROM, or Flash memory), a portable compact disc read-only memory (CDROM), digital tape, and other non-transitory media.

The various embodiments described above can be combined to provide further embodiments. To the extent that they are not inconsistent with the specific teachings and definitions herein, at least the following are incorporated herein by reference in their entirety: U.S. Provisional Patent Application Ser. No. 62/438,725, U.S. Non-Provisional patent application Ser. No. 15/848,265 (U.S. Publication Number 2018/0180885), U.S. Non-Provisional patent application Ser. No. 15/848,388 (U.S. Publication Number 2018/0180886), U.S. Provisional Patent Application Ser. No. 62/450,218, U.S. Non-Provisional patent application Ser. No. 15/852,188 (U.S. Publication Number 2018/0210215), U.S. Non-Provisional patent application Ser. No. 15/852,282, (U.S. Publication Number 2018/0210213), U.S. Non-Provisional patent application Ser. No. 15/852,205 (U.S. Publication Number 2018/0210216), U.S. Provisional Patent Application Ser. No. 62/575,677, U.S. Provisional Patent Application Ser. No. 62/591,550, U.S. Provisional Patent Application Ser. No. 62/597,294, U.S. Provisional Patent Application Ser. No. 62/608,749, U.S. Provisional Patent Application Ser. No. 62/609,870, U.S. Provisional Patent Application Ser. No. 62/591,030, U.S. Provisional Patent Application Ser. No. 62/620,600, U.S. Provisional Patent Application Ser. No. 62/576,962, U.S. Provisional Patent Application Ser. No. 62/760,835, U.S. patent application Ser. No. 16/201,664, U.S. Non-Provisional patent application Ser. No. 16/168,690, U.S. Non-Provisional patent application Ser. No. 16/171,206, and/or PCT Patent Application PCT/CA2018051344. Aspects of the embodiments can be modified, if necessary, to employ systems, circuits and concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An optical engine, comprising:
a base substrate;
a plurality of laser diodes, each of the plurality of laser diodes bonded directly or indirectly to the base substrate;
a cap comprising at least one wall that, with the base substrate, defines an interior volume sized and dimensioned to receive at least the plurality of laser diodes, the cap being bonded to the base substrate to provide a hermetic or partially hermetic seal between the interior volume of the cap and a volume exterior to the cap; and
a photonic integrated circuit comprising at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge.

2. The optical engine of claim 1, further comprising:
a plurality of coupling lenses positioned between the plurality of laser diodes and the input optical edge of the photonic integrated circuit, each of the plurality of coupling lenses positioned and oriented to couple respective ones of the beams of light emitted from the plurality of laser diodes to the at least one input optical edge of the photonic integrated circuit.

3. The optical engine of claim 1 wherein each of the plurality of laser diodes are positioned immediately adjacent the at least one optical input edge of the photonic integrated circuit.

4. The optical engine of claim 1 wherein the at least one optical input edge of the photonic integrated circuit is positioned inside the interior volume and the at least one optical output edge of the photonic integrated circuit is positioned outside of the interior volume.

5. The optical engine of claim 1 wherein the cap comprises at least one optical window positioned and oriented to allow beams of light emitted from the plurality of laser diodes to exit the interior volume.

6. The optical engine of claim 1, further comprising:
a collimation lens positioned and oriented to receive and collimate the aggregate beam of light from the output optical edge of the photonic integrated circuit.

7. (canceled)

8. The optical engine of claim 1, further comprising at least one diffractive optical element positioned and oriented to receive the aggregate beam of light, in operation, the at least one diffractive optical element provides wavelength dependent focus correction for the aggregate beam of light.

9. The optical engine of claim 5 wherein the cap comprises a rectangular shaped sidewall, and the optical window delimits a portion of the sidewall.

10. The optical engine of claim 1, further comprising:
a plurality of chip submounts bonded to the base substrate, wherein each of the laser diodes are bonded to a corresponding one of the plurality of chip submounts.

11-12. (canceled)

13. The optical engine of claim 1, further comprising at least one laser diode driver circuit operatively coupled to the plurality of laser diodes to selectively drive current to the plurality of laser diodes.

14. The optical engine of claim 13 wherein the at least one laser diode driver circuit is bonded to a first surface of the base substrate, and the plurality of laser diodes and the cap are bonded to a second surface of the base substrate, the second surface of the base substrate opposite the first surface of the base substrate.

15. The optical engine of claim 13 wherein the at least one laser diode driver circuit, the plurality of laser diodes, and the cap are bonded to a first surface of the base substrate.

16. The optical engine of claim 1 wherein each of the laser diodes comprises one of an edge emitter laser or a vertical-cavity surface-emitting laser (VCSEL).

17. The optical engine of claim 1 wherein the photonic integrated circuit comprises a plurality of waveguides, each waveguide of the plurality of waveguides to receive laser light from a respective laser diode of the plurality of laser diodes.

18. The optical engine of claim 17, wherein each waveguide of the plurality of waveguides is optimized to receive and output laser light having a wavelength corresponding to the wavelength of laser light received from the respective laser diode.

19. The optical engine of claim 17 wherein the plurality of waveguides comprises a waveguide combiner.

20. The optical engine of claim 19, wherein the waveguide combiner comprises at least one of: a directional coupler, Y-branch, whispering gallery mode, or multi-mode interface coupler.

21. The optical engine of claim 17 wherein each waveguide of the plurality of waveguides includes an input facet to receive laser light from a respective laser diode of the plurality of laser diodes and an output facet to output the received laser light, a spacing between the output facets of each waveguide being smaller than a spacing between the input facets of each waveguide.

22. A laser projector, comprising:
an optical engine, comprising:
a base substrate;
a plurality of laser diodes, each of the plurality of laser diodes bonded directly or indirectly to the base substrate;
at least one laser diode driver circuit operatively coupled to the plurality of laser diodes to selectively drive current to the plurality of laser diodes;
a cap comprising at least one wall and at least one optical window that, together with the base substrate, define an interior volume sized and dimensioned to receive at least the plurality of laser diodes, the cap being bonded to the base substrate to provide a hermetic or partially hermetic seal between the interior volume of the cap and a volume exterior to the cap, and the optical window positioned and oriented to allow beams of light emitted from the plurality of laser diodes to exit the interior volume;
a photonic integrated circuit bonded to the base substrate proximate the optical window of the cap, the photonic integrated circuit comprising at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge; and
a plurality of coupling lenses bonded to the base substrate between the optical window of the cap and the input optical edge of the photonic integrated circuit, each of the plurality of coupling lenses positioned and oriented to couple respective ones of the beams of light emitted from the plurality of laser diodes to the at least one input optical edge of the photonic integrated circuit; and
at least one scan mirror positioned to receive the aggregate beam of light output at the output optical edge of the photonic integrated circuit, the at least one scan mirror controllably orientable to redirect the aggregate beam of light over a range of angles.

23. A wearable heads-up display (WHUD), comprising:
a support structure that in use is worn on the head of a user;
a laser projector carried by the support structure, the laser projector comprising:
an optical engine, comprising:
a base substrate;
a plurality of laser diodes, each of the plurality of laser diodes bonded directly or indirectly to the base substrate;
at least one laser diode driver circuit operatively coupled to the plurality of laser diodes to selectively drive current to the plurality of laser diodes;
a cap comprising at least one wall and at least one optical window that, together with the base substrate, define an interior volume sized and dimensioned to receive at least the plurality of laser diodes, the cap being bonded to the base substrate to provide a hermetic or partially hermetic seal between the interior volume of the cap and a volume exterior to the cap, and the optical window positioned and oriented to allow beams of light emitted from the plurality of laser diodes to exit the interior volume;
a photonic integrated circuit bonded to the base substrate proximate the optical window of the cap, the photonic integrated circuit comprising at least one optical input edge and at least one optical output edge, in operation, the photonic integrated circuit receives a plurality of beams of light at the at least one optical input edge and wavelength multiplexes the plurality of beams of light to provide an aggregated beam of light at the output optical edge; and
a plurality of coupling lenses bonded to the base substrate between the optical window of the cap and the input optical edge of the photonic integrated circuit, each of the plurality of coupling lenses positioned and oriented to couple respective ones of the beams of light emitted from the plurality of laser diodes to the at least one input optical edge of the photonic integrated circuit; and
at least one scan mirror positioned to receive the aggregate beam of light output at the output optical edge of the photonic integrated circuit, the at least one scan mirror controllably orientable to redirect the aggregate beam of light over a range of angles.

24. The WHUD of claim 23, further comprising:
a transparent combiner carried by the support structure and positioned within a field of view of the user, in operation the transparent combiner directs laser light from an output of the laser projector into the field of view of the user.
